(19) United States
(12) Patent Application Publication
(10) Pub. No.: US 2022/0199695 A1
(43) Pub. Date: Jun. 23, 2022

(54) DISPLAY APPARATUS, LIGHT EMITTING DEVICE, AND LIGHT EMITTING MEMBER

(71) Applicant: SONY GROUP CORPORATION, TOKYO (JP)

(72) Inventors: MIKIO TAKIGUCHI, TOKYO (JP); TAKAHIRO KOYAMA, TOKYO (JP); TOYOHARU OOHATA, TOKYO (JP)

(21) Appl. No.: 17/600,736

(22) PCT Filed: Mar. 27, 2020
(86) PCT No.: PCT/JP2020/014182

§ 371 Date: Oct. 1, 2021

(30) Foreign Application Priority Data
Apr. 12, 2019 (JP) 2019-076398

(51) Int. Cl. H01L 27/32; H01L 25/18; H01L 27/15

(52) U.S. Cl. CPC H01L 27/322; H01L 25/18; H01L 27/3244; H01L 2251/5369; H01L 27/153

(57) ABSTRACT

The display apparatus includes a plurality of light emitting device units each including: a light generating unit 11, 21, or 31; a wavelength conversion layer 12, 22, or 32 including a color conversion layer 13, 23, or 33 that includes a particulate color conversion material; and a first light emitting device 10, a second light emitting device 20, or a third light emitting device 30 including a wavelength selection layer 14, 24, or 34. The wavelength of light emitted from the third wavelength selection layer 34 is longer than the wavelength of light emitted from the second wavelength selection layer 24 and the wavelength of light emitted from the first wavelength selection layer 14. The wavelength of light emitted from the second wavelength selection layer 24 is longer than the wavelength of light emitted from the first wavelength selection layer 14. Further, T₁<T₂≤T₃ is satisfied, where T₁ denotes the thickness of the first color conversion layer 14, T₂ denotes the thickness of the second color conversion layer 24, and T₃ denotes the thickness of the third color conversion layer 34.

### TECHNICAL FIELD

The present disclosure relates to a display apparatus, a light emitting device, and a light emitting member.

### BACKGROUND

Recently, a liquid crystal display apparatus provided with a backlight including blue LEDs and YAG phosphors has been widely used. A YAG phosphor has a high quantum yield, but its emission spectrum extends over a very wide range from 500 nm to 750 nm. Additionally, because green light and red light are extracted from such a wide emission spectrum range using a color filter, a YAG phosphor exhibits a low utilization efficiency. Thus, to improve the energy utilization efficiency and increase color gamut, a backlight system using a quantum dot (QD) sheet has been proposed (see, for example, Japanese Unexamined Patent Application Publication (Translation of PCT Application) No. 2013-544018). However, the energy utilization efficiency of this system is still low because red light, green light, and blue light are emitted from the quantum dot sheet before green light and red light are extracted using a color filter. To solve such a problem, a structure including a red light emitting portion having quantum dots emitting red light, a green light emitting portion having quantum dots emitting green light, and a blue light emitting portion having quantum dots emitting blue light on an array of LEDs has been proposed (e.g., Japanese Unexamined Patent Application Publication (Translation of PCT Application) No. 2018-517157).

### CITATION LIST

### Patent Literature

PTL 1: Japanese Unexamined Patent Application Publication (Translation of PCT Application) No. 2013-544018

PTL 2: Japanese Unexamined Patent Application Publication (Translation of PCT Application) No. 2018-517157

### SUMMARY OF THE INVENTION

### Problem to be Solved by the Invention

The structure disclosed in Japanese Unexamined Patent Application Publication (Translation of PCT Application) No. 2018-517157 exhibits high energy utilization efficiency because excitation light from an LED is color-converted in each light emitting portion (subpixel). However, forming three types of light emitting portions (subpixels) having quantum dots emitting different colors by, for example, an ink jet printing method requires a long tact time, which increases the manufacturing cost. Further, the light emitting portions having quantum dots are collectively formed by a combination of a coating method and a photolithography technique, which reduces the manufacturing cost. However, the quantum dots in an unnecessary region are removed by repeating the coating method and the photolithography technique for each formation of the red light emitting portion, the green light emitting portion, and the blue light emitting portion, which results in low material utilization efficiency of the quantum dots and an increase in the production cost.

Accordingly, an object of the present disclosure is to provide a display apparatus, a light emitting device, and a light emitting member that make it possible to achieve both an improvement in light utilization efficiency and a reduction in manufacturing costs.

### Means for Solving the Problems

A display apparatus according to the present disclosure that achieves the object described above includes

a plurality of light emitting device units each including a first light emitting device, a second light emitting device, and a third light emitting device, in which

the first light emitting device includes

a first light generating unit that generates light having a wavelength λ₀,

a first wavelength conversion layer that includes a first color conversion layer having a thickness T₁ and including a particulate color conversion material, the particulate color conversion material converting the color of the light having the wavelength λ₀ emitted from the first light generating unit, and

a first wavelength selection layer that the light emitted from the first wavelength conversion layer enters and that emits light having a wavelength λ₁′,

the second light emitting device includes

a second light generating unit that generates light having a wavelength λ₀,

a second wavelength conversion layer that includes a second color conversion layer having a thickness T₂ and including a particulate color conversion material, the particulate color conversion material converting the color of the light having the wavelength λ₀ emitted from the second light generating unit, and

a second wavelength selection layer that the light emitted from the second wavelength conversion layer enters and that emits light having a wavelength λ₂′,

the third light emitting device includes

a third light generating unit that generates light having a wavelength λ₀,

a third color conversion layer that includes a third color conversion layer having a thickness T₃ and including a particulate color conversion material, the particulate color conversion material converting the color of the light having the wavelength λ₀ emitted from the third light generating unit, and

a third wavelength selection layer that the light emitted from the third wavelength conversion layer enters and that emits light having a wavelength λ₃′ (where λ₁′<λ₂′<λ₃′ holds), and

T₁<T₂≤T₃ is satisfied.

Note that, when T₂=T₃ holds, an average value T₂₋ₐᵥₑ of the thickness T₂ and an average value of a thickness T₃₋ₐᵥₑ satisfy the relation represented by, for example,

0.9≤T₂₋ₐᵥₑ/T₃₋ₐᵥₑ≤1.1.

For instance, when

T₂₋ₐᵥₑ/T₃₋ₐᵥₑ<0.9

holds,
T₂<T₃ is satisfied. The same applies to the following description.

A light emitting device according to the present disclosure that achieves the object described above includes

a light generating unit that generates light having a wavelength λ₀; and

a wavelength conversion layer that includes a color conversion layer including a particulate color conversion material, the particulate color conversion material converting the color of the light having the wavelength λ₀ emitted from the light generating unit, in which

the color conversion layer has a thickness determined on the basis of the wavelength λ″ (where λ″>λ₀ holds) of light emitted from the wavelength conversion layer.

A light emitting member according to the present disclosure that achieves the object described above includes a first light emitting portion, a second light emitting portion, and a third light emitting portion, in which

the first light emitting portion includes a first wavelength conversion layer including a first color conversion layer, the first color conversion layer having a thickness T₁ and including a particulate color conversion material, the particulate color conversion material converting a color of light having a wavelength λ₀ emitted from a light generating unit,

the second light emitting portion includes a second wavelength conversion layer including a second color conversion layer, the second color conversion layer having a thickness T₂ and including a particulate color conversion material, the particulate color conversion material converting a color of light having a wavelength λ₀ emitted from a light generating unit,

the third light emitting portion includes a third wavelength conversion layer including a third color conversion layer, the third color conversion layer having a thickness T₃ and including a particulate color conversion material, the particulate color conversion material converting a color of light having a wavelength λ₀ emitted from a light generating unit,

T₁<T₂≤T₃ is satisfied, and

the peak wavelength of a light spectrum of light emitted from the first wavelength conversion layer is different from the peak wavelength of a light spectrum of light emitted from the second wavelength conversion layer and the peak wavelength of a light spectrum of light emitted from the third wavelength conversion layer.

Note that, when T₁<T₂=T₃ holds, the peak wavelength λ₂₋ₚₑₐₖ″ of the light spectrum of the light emitted from the second wavelength conversion layer is the same as the peak wavelength λ₃₋ₚₑₐₖ″ of the light spectrum of the light emitted from the third wavelength conversion layer. On the other hand, when T₁<T₂<T₃ holds, the peak wavelength λ₂₋ₚₑₐₖ″ of the light spectrum of the light emitted from the second wavelength conversion layer is different from the peak wavelength λ₃₋ₚₑₐₖ″ of the light spectrum of the light emitted from the third wavelength conversion layer. Specifically, λ₂₋ₚₑₐₖ″<λ₃₋ₚₑₐₖ″ holds.

### BRIEF DESCRIPTION OF DRAWINGS

FIG. 1A is a schematic partial end view of a display apparatus and a light emitting device of Example 1, FIG. 1B is a diagram schematically illustrating an arrangement of wavelength selection layers in the display apparatus of Example 1, and FIG. 1C is a diagram schematically illustrating an arrangement of a first electrode and a second electrode in the display apparatus of Example 1.

FIG. 2A is a schematic partial end views of the display apparatus and the light emitting device of Example 1, and FIG. 2B is a schematic partial end views of a light emitting member of Example 1.

FIG. 3A and FIG. 3B are schematic partial end views of a light generating unit and the like for explaining a manufacturing process of the display apparatus of Example 1.

FIG. 4A and FIG. 4B are schematic partial end views of the light generating unit and the like for explaining the manufacturing process of the display apparatus of Example 1, following FIG. 3B.

FIG. 5 is a schematic partial end view of the light generating unit and the like for explaining the manufacturing process of the display apparatus of Example 1, following FIG. 4B.

FIG. 6A is a schematic partial end view of a display apparatus and a light emitting device of Example 2, and FIG. 6B is a schematic partial end view of a display apparatus and a light emitting device of Modification Example-1 of Example 2.

FIG. 7A is a schematic partial end view of Modification Example-2 of Example 2, and FIG. 7B is a schematic partial end view of Modification Example-3 of Example 2.

FIG. 8A and FIG. 8B are schematic partial end views illustrating a state of the display apparatus of Modification Example-1 of Example 2 during the manufacture thereof.

FIG. 9 is a schematic partial end view illustrating a state of the display apparatus of Modification Example-1 of Example 2 during the manufacture thereof, following the FIG. 8B.

FIG. 10A is a schematic partial end view of a display apparatus and a light emitting device of Example 3, and FIG. 10B is a schematic partial end view of a display device and a light emitting device of Modification Example-1 of Example 3.

FIG. 11A is a schematic partial end view of a display apparatus and a light emitting device of Modification Example-2 of Example 3, and FIG. 11B is a schematic partial end view of a display apparatus and a light emitting device of Example 4.

FIG. 12A is a schematic partial end view of a display apparatus and a light emitting device of Example 5, and FIG. 12B is a schematic partial end view of a display apparatus and a light emitting device of Modification Example-1 of Example 5.

FIG. 13 is a schematic partial end view of a display apparatus and a light emitting device of Modification Example-2 of Example 5.

FIG. 14A is a schematic partial end view of a display apparatus and a light emitting device of Example 6, and FIG. 14B is a schematic partial end view of a display apparatus and a light emitting device of Modification Example-1 of Example 6.

FIG. 15 is a schematic partial end view of a display apparatus and a light emitting device of Example 7.

FIG. 16A is a schematic partial end view of a display apparatus and a light emitting device of Example 8, and FIG. 16B is a schematic diagram illustrating the arrangement of a sidewall, a light reflection layer, and a cutout of the display apparatus of Example 8.

FIG. 17A is a schematic partial end view of a display apparatus and a light emitting device of Example 9, and FIG. 17B is a schematic partial end view of a display apparatus and a light emitting device of Example 10.

FIG. 18A and FIG. 18B are schematic partial end views of a display apparatus and a light emitting device of modification examples of Examples.

FIG. 19 is a graph illustrating an example of the absorption spectra of a quantum dot emitting green light and a quantum dot emitting red light.

FIG. 20 is a graph illustrating the results of ray tracing simulation of the light emission spectra observed when a solution of mixture of quantum dots emitting green light and quantum dots emitting red light was changed in thickness.

FIG. 21A is a graph illustrating the light conversion and extraction efficiency of red light, green light, and blue light observed when the color conversion layer was changed in thickness, and FIG. 21B is a graph illustrating the ratio between the amount of red light, the amount of green light, and the amount of blue light.

### MODES FOR CARRYING OUT THE INVENTION

Hereinafter, the present disclosure will be described on the basis of examples with reference to the accompanying drawings. The present disclosure, however, is not limited to these examples, and various numerical values and materials in the examples are illustrative. Note that the description is made in the following order:
1. Outline description of display apparatus, light emitting device, and light emitting member of the present disclosure
2. Example 1 (display apparatus, light emitting device, and light emitting member)
3. Example 2 (Modification of Example 1)
4. Example 3 (Modification of Examples 1 and 2)
5. Example 4 (Modification of Example 1 to 3)
6. Example 5 (Modification of Examples 1 to 4)
7. Example 6 (Modification of Examples 1 to 5)
8. Example 7 (Modification of Examples 1 to 6)
9. Example 8 (Modification of Examples 1 to 7)
10. Example 9 (Modification of Examples 1 to 8)
11. Example 10 (Modification of Examples 1 to 9)
12. Other

### Outline Description of Display Apparatus, Light Emitting Device, and Light Emitting Member of the Present Disclosure

Hereinafter, the display apparatus of the present disclosure and the light emitting member of the present disclosure may be collectively referred to simply as a “display apparatus and the like of the present disclosure”. In that case, the light emitting device is read as a light emitting unit as required.

The light emitting device of the present disclosure may include a particulate color conversion material that includes first quantum dots and second quantum dots. Further, the light emitting device of the present disclosure including such a preferable form may be further provided with a wavelength selection layer that the light emitted from a wavelength conversion layer enters.

The particulate color conversion material in each light emitting device in the display apparatus and the like of the present disclosure may include the first quantum dots that convert light having a wavelength λ₀ into light having a wave λ₂″ (specifically, λ₂₋ₚₑₐₖ″) (where λ₂″>λ₀ holds), and the second quantum dots that convert light having a wavelength λ₀ into light having a wavelength λ₃″ (specifically, λ₃₋ₚₑₐₖ″) (where λ₃″>λ₂″>λ₀ holds). Here, it is preferable that the second quantum dots further convert light having a wave λ₂″ (specifically, λ₂₋ₚₑₐₖ″) into light having a wave λ₃″ (specifically, λ₃₋ₚₑₐₖ″). Further, in that case, it is preferable that T₁<T₂=T₃ be satisfied. Here, the thicknesses T₁, T₂, and T₃ preferably satisfy a relation represented by, but not limited to,

1≤(T₂=T₃)/T₁,

and more preferably,

1≤(T₂=T₃)/T₁≤100.

Alternatively, in that case, it is preferable that T₁<T₂<T₃ be satisfied. Here, the thicknesses T₁, T₂, and T₃ preferably satisfy a relation represented by, but not limited to,

2≤T₂/T₁,

3≤T₃/T₁, and

1.5≤T₃/T₂, and more preferably,

2≤T₂/T₁≤100,

3≤T₃/T₁≤100, and

1.5≤T₃/T₂≤10.

In the display apparatus and the like of the present disclosure including the various preferable forms described above, the wavelength conversion layer in each light emitting device may further include a spacer layer. The total thickness of the thickness of the spacer layer and the thickness of the color conversion layer may be equal between the light emitting devices. The spacer layer may be positioned on a light incident side of the color conversion layer or a light emitting side of the color conversion layer. The phrase “thickness is equal” means that

0.9≤T_{1-Total}/T_{2-Total}≤1.1,

0.9≤T_{2-Total}/T_{3-Total}≤1.1, and

0.9≤T_{1-Total}/T_{3-Total}≤1.1

are satisfied, where T_{1-Total} denotes the total thickness of the thickness of the spacer layer and the thickness of the color conversion layer in the first light emitting device, T_{2-Total} denotes the total thickness of the thickness of the spacer layer and the thickness of the color conversion layer in the second light emitting device, and T_{3-Total} denotes the total thickness of the thickness of the spacer layer and the thickness of the color conversion layer in the third light emitting device. The same applies to the following description. It is to be noted that, in general, the state satisfying such expressions in terms of the thicknesses may be expressed as “satisfying within a range of ±10% of thickness variation”. Examples of the material of the spacer layer may include a transparent member, such as an acrylic ultraviolet curable resin, an epoxy-based ultraviolet curable resin, a silicone-based thermosetting resin, and an epoxy-based thermosetting resin.

Further, in the display apparatus and the like of the present disclosure including the various preferable forms described above, the wavelength conversion layer may include light scattering particles, or the wavelength selection layer may include light scattering particles. Alternatively, in the display apparatus and the like of the present disclosure including the various preferable forms described above, the wavelength conversion layer in each light emitting device may further include a light scattering particle layer. In this case, the total thickness of the thickness of the light-scattering particle layer and the color conversion layer may be equal between the light emitting devices. The light-scattering particle layer is preferably provided on the light emitting side of the color conversion layer. The phrase “thickness is equal” means that

0.9≤T_{1-Total}′/T_{2-Total}′≤1.1

0.9≤T_{2-Total}′/T_{3-Total}′≤1.1, and

0.9≤≤T_{1-Total}′/T_{3-Total}′≤1.1

are satisfied, where T_{1-Total}′ denotes the total thickness of the thickness of a first light-scattering particle layer and the thickness of a first color conversion layer in the first light emitting device, T_{2-Total}′ denotes the total thickness of the thickness of a second light-scattering particle layer and the thickness of a second color conversion layer in the second light emitting device, and T_{3-Total}′ denotes the total thickness of the thickness of a third light-scattering particle layer and the thickness of a third color conversion layer in the third light emitting device.

Examples of the light scattering particles or the light scattering particles included in the light-scattering particle layer may include SiO₂, Al₂O₃, and TiO₂. Using the light scattering particles allows the light emitted from the light emitting device to be in the Lambertian light distribution state or have light distribution characteristics close to the Lambertian light distribution state.

Further, in the display apparatus and the like of the present disclosure including the various preferable forms described above, an on-chip micro-lens may be provided more adjacent to the light-emitting side of each light emitting device than the wavelength selection layer is. The on-chip micro-lens may be an on-chip micro-lens having a known configuration or structure. Examples of the material of the on-chip micro-lens may include a transparent resin material, such as an acrylic resin, an epoxy-based resin, a polycarbonate resin (PC), a polyimide-based resin, a polymethyl methacrylate resin (PMMA), a polyarylate resin (PAR), a polyethylene terephthalate resin (PET), and an ABS resin, and glass. The on-chip micro-lens may be obtained by melt-flowing or etching back a transparent resin material. Alternatively, the on-chip micro-lens may be obtained by a combination of a photolithography technique and an etching method using a gray-tone mask. Still alternatively, the on-chip micro-lens may be obtained by forming a transparent resin material into a lens shape by a nano-imprint method.

Further, in the display apparatus and the like of the present disclosure including the various preferable forms described above, a light generating unit of each light emitting device may be coupled to drive circuitry provided on a base. The drive circuitry may have a known configuration or structure to drive the light generating unit. Examples of the method of coupling the light generating unit and the drive circuitry provided on the base may include, a method using a bump including solder, indium, gold (Au) or the like, a plating method, a chip-on-chip method, a method using a through-chip via (TCV) or through-silicon via (TSV), and metal-metal junction, such as Cu—Cu junction. The base may be, for example, a silicon semiconductor base, a glass base, a GaN base, or a SiC base.

Further, in the display apparatus and the like of the present disclosure including the various preferable forms described above, a transparent material member may be provided between the light generating unit and the wavelength conversion layer in each light emitting device. Alternatively, the transparent material member may be provided between the wavelength conversion layer and the wavelength selection layer in each light emitting device. Examples of the material of the transparent material member may include an organic polymer (polymeric products such as a flexible plastic film, a plastic sheet, or a plastic base including a polymeric material), such as polymethyl methacrylate (PMMA), polyvinyl alcohol (PVA), polyvinyl phenol (PVP), polyethersulfone (PES), polyethylene terephthalate (PET), polyethylene naphthalate (PEN), polybutylene terephthalate (PBT), acetyl cellulose, tetraacetyl cellulose, polyphenylene sulfide, polycarbonate (PC), polyethylene (PE), polypropylene (PP), polyvinylidene fluoride, brominated phenoxy, polyamide, polyimide, polystyrene, polyarylate, polysulfone such as polyester sulfone, and polyolefine. Another examples of the material of the transparent material member may include a glass base and a sapphire base. Alternatively, a space (gap) may be provided more adjacent to the light generating unit than the transparent material member is. For example, the space (gap) may be provided between the wavelength conversion layer and the wavelength selection layer, or between the light generating unit and the wavelength conversion layer. In the light emitting member of the present disclosure, the first wavelength conversion layer, the second wavelength conversion layer, and the third wavelength conversion layer may be formed on the transparent material member.

Further, in the display apparatus and the like of the present disclosure including the various preferable forms described above, the light generating unit of each light emitting device may include a light emitting diode (LED). In this case, the LED may include at least a first compound semiconductor layer, an active layer, and a second compound semiconductor layer from the wavelength conversion layer side. The first compound semiconductor layer, the active layer, and the second compound semiconductor layer are laminated into a laminated light emitting structure. The laminated light emitting structure may include, for example, a GaN-based compound semiconductor (including AlGaN mixed crystal, AlGaInN mixed crystal, or GaInN mixed crystal), an AlGaInAs-based compound semiconductor, an AlGaInP-based compound semiconductor, a ZnSe-based compound semiconductor (including ZnS, ZnSSe, or ZnMgSSe, for example), or a ZnO-based compound semiconductor. To drive the light generating unit, the laminated light emitting structure is coupled to an electrode. Examples of the material of the electrode may include Pd, ITO, a AuGe/NiAu laminated structure, a Ti/Pt/Au laminated structure, and an Ni/Au laminated structure. Alternatively, the light generating unit of each light emitting device may be an organic electroluminescent device. The organic electroluminescent (EL) device may have a known configuration or structure. The first light generating unit, the second light generating unit, and the third light generating unit that generate light having a wavelength λ₀ may have the same configuration or structure.

Further, in the display apparatus and the like of the present disclosure including the various preferable forms described above, a light shutter means may be provided between the wavelength conversion layer and the wavelength selection layer in each light emitting device. The light shutter means may be, for example, a liquid crystal display of a transmission type.

In the display apparatus and the like of the present disclosure, the light emitting device unit may include a fourth light emitting device, a fifth light emitting device, . . . in addition to the first light emitting device, the second light emitting device, and the third light emitting device.

In the display apparatus and the like of the present disclosure including the various preferable forms described above, it is preferable that the light emitting devices be separated by a sidewall (partition wall). Examples of the material of the sidewall (partition wall) may include a resist material, various metals, various alloys, various resins, and insulating materials such as SiO₂ and SiN. Further, the sidewall (partition wall) may surround each light generating unit and a coupling portion between each light generating unit and the drive circuitry. Optionally, a light reflection layer may be formed on an inner surface of the sidewall. Examples of the material of the light reflection layer may include Ag, Au, Al, and a multilayer film including dielectric substances such as SiO₂, Al₂O₃, TiO₂, and Ta₂O₅.

In the display apparatus and the like of the present disclosure including the various preferable forms described above, the total thickness of the thickness of the wavelength conversion layer and the thickness of the wavelength selection layer may be equal between the light emitting devices. The phrase “thickness is equal” means that

0.9≤T_{1-Total}″/T_{2-Total}″≤1.1

0.9≤T_{2-Total}″/T_{3-Total}″≤1.1, and

0.9≤T_{1-Total}″/T_{3-Total}″≤1.1

are satisfied, where T_{1-Total} denotes the total thickness of the thickness of the wavelength conversion layer and the thickness of the wavelength selection layer in the first light emitting device, T_{2-Total} denotes the total thickness of the thickness of the wavelength conversion layer and the thickness of the wavelength selection layer in the second light emitting device, and T_{3-Total} denotes the total thickness of the thickness of the wavelength conversion layer and the thickness of the wavelength selection layer in the third light emitting device.

Additionally, in the display apparatus and the like of the present disclosure including the various preferable forms described above, an optical crosstalk suppression unit may be provided in a region between the light emitting devices.

Herein, the light having a wavelength λ₀ is generated in the light generating unit. The light generated in the light generating unit, however, may have a narrow spectrum width (i.e., may have one or more spectral peaks) or a certain (wide) spectrum width. The wavelength range (full width half maximum (FWHM)) of the wavelength λ₀ may be in a range of 10 nm to 50 nm. The light having the wavelength λ₁′ emitted from the first wavelength selection layer may be blue light, specifically, light having a wavelength range (FWHM) of 430 nm to 500 nm, for example. The light having the wavelength λ₂′ emitted from the second wavelength selection layer may be green light, specifically, light having a wavelength range (FWHM) of 500 nm to 570 nm, for example. The light having the wavelength λ₃′ emitted from the third wavelength selection layer may be red light, specifically, light having a wavelength range (FWHM) of 610 nm to 750 nm, for example. Note that λ₁′<λ₂′<λ₃′ is satisfied. Specifically, λ₁′<λ₂′<λ₃′ is satisfied when λ₁₋ₚₑₐₖ′<λ₂₋ₚₑₐₖ′<λ₃₋ₚₑₐₖ′ holds, where λ₁₋ₚₑₐₖ′ denotes the peak wavelength of the light spectrum of the wavelength λ₁′, λ₂₋ₚₑₐₖ′ denotes the peak wavelength of the light spectrum of the wavelength λ₂′, and λ₃₋ₚₑₐₖ′ denotes the peak wavelength of the light spectrum of the wavelength λ₃′.

Additionally, the light of having wavelength λ₂″ emitted mainly from the second wavelength conversion layer may be green light, specifically, light having a wavelength range (FWHM) of 500 nm to 570 nm, for example. The light having the wavelength λ₃″ emitted mainly from the third wavelength conversion layer may be red light, specifically, light having a wavelength range (FWHM) of 610 nm to 750 nm, for example.

The various forms of the light emitting device in the display apparatus and the like of the present disclosure including the various preferable forms described above may be applied to the light emitting device of the present disclosure as appropriate.

As the size (diameter) of a quantum dot decreases, the band gap energy increases, and the wavelength of light emitted from the quantum dot shortens. That is, a quantum dot having a smaller size emits light having a shorter wavelength (light on the blue light side), and a quantum dot having a larger size emits light having a longer wavelength (light on the red light side). Thus, quantum dots emitting light having a desired wavelength (converting the color of light into a desired color) may be produced by using the same material for the quantum dots and adjusting the size of the quantum dots. For example, the first quantum dot and the second quantum dot may be formed of different materials; however, it is desirable that the first quantum dot and the second quantum dot be formed of the same material (but having different diameters) to simplify the structure and simplify the manufacturing process. That is, it is preferable that the first color conversion layer, the second color conversion layer, and the third color conversion layer include the same particulate color conversion material. The quantum dot preferably has a core shell-structure.

Examples of the material of the first quantum dot or the second quantum dot may include, but not limited to, Si; Se; chalcopyrite-based compounds such as CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂; perovskite-based materials; III-V group compounds such as GaAs, GaP, InP, InAs, InGaAs, AlGaAs, InGaP, AlGaInP, InGaAsP, and GaN; CdSe, CdSeS, CdS, CdTe, In₂Se₃, In₂S₃, Bi₂Se₃, Bi₂S₃, ZnSe, ZnTe, ZnS, HgTe, HgS, PbSe, PbS, and TiO₂.

The color conversion layer includes the particulate color conversion material. Alternatively, the color conversion layer includes the particulate color conversion material embedded in a filler or a matrix. Examples of the filler may include a polypropylene resin, a polyethylene resin, a polystyrene resin, an AS resin, an ABS resin, a methacrylic resin, a polyvinyl chloride resin, a polyacetal resin, a polyamide resin, a polycarbonate resin, a modified polyphenylene ether resin, a polybutylene terephthalate resin, a polyethylene terephthalate resin, a polysulfone resin, a polyethersulfone resin, a polyphenylene sulfide resin, a polyamide imide resin, a polymethylpentene resin, a liquid crystal polymer resin, an epoxy resin, a phenol resin, a urea resin, a melanine resin, a diallylphthalate resin, an unsaturated polyester resin, a polyimide resin, a polyurethane resin, a silicone resin, an acrylic resin, and a mixture of these resins.

The wavelength selection layer (wavelength selection means) may be, for example, a color filter layer including a color resist material, a photonic crystal or a wavelength selection element to which a plasmon is applied (a color filter having a conductor lattice structure provided with a conductor thin film having a lattice-shaped hole structure, see, for example, Japanese Unexamined Patent Application Publication No. 2008-177191), or a thin film including an inorganic material such as amorphous silicon.

The display apparatus of the present disclosure may be applied to various display apparatuses, such as a video wall, a smart phone, a television receiver, a display or monitor for a personal computer and the like, a display for AR/VR, a projector, a head-up display, a head-mounted display, and a wearable device (a smart watch).

### Example 1

Example 1 relates to the display apparatus, the light emitting device, and the light emitting member of the present disclosure.

Before the display apparatus, the light emitting device, and the light emitting member of Example 1 are described, the basic operation and the like of the display apparatus of Example 1 is described first hereinafter.

The relationship between a light absorption rate A of the color conversion layer, an absorption coefficient a standardized by the film thickness, and an optical path length L is represented by the following expression (1):

A=1−exp(−α×L) (1)

where the absorption coefficient a is substantially proportional to the concentration of the quantum dots.

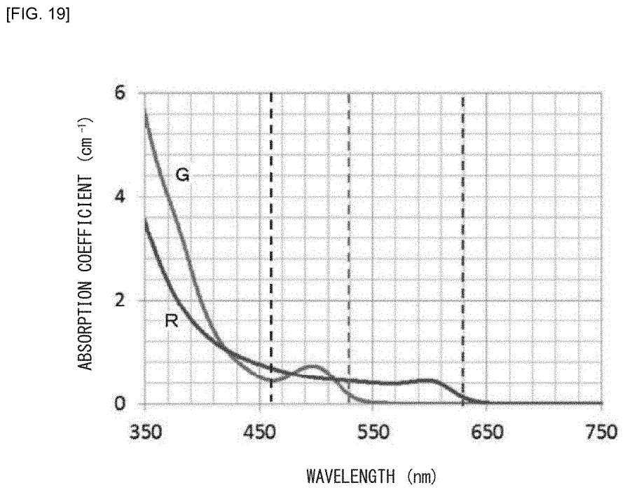

The absorption spectrum “G” of the quantum dot emitting green light (referred to as “quantum dot G” for convenience) and the absorption spectrum “R” of the quantum dot emitting red light (referred to as “quantum dot R” for convenience) are illustrated in FIG. 19. The quantum dot G absorbs a large amount of blue light serving as excitation light, a slight amount of green light, and no red light. The quantum dot R absorbs blue light and green light serving as excitation light, and absorbs a portion of red light. Having such characteristics, the quantum dot R in a mixture of the quantum dot G and the quantum dot R absorbs a portion of the green light emitted from the quantum dot G and converts the absorbed light into red light. Accordingly, as the thickness of the color conversion layer increases, an increased amount of the components in the green light emitted from the quantum dot G is absorbed by the quantum dot R, and re-emitted as red light. As a result, the ratio of the red light increases. Further, as the thickness of the color conversion layer increases, an increased amount of the excitation light is absorbed by the quantum dot G and the quantum dot R. As a result, the ratio of the blue light emitted from the color conversion layer decreases. As described above, it is possible to adjust the ratio between the amount of red light, the amount of green light, and the amount of blue light by controlling the thickness of the color conversion layer.

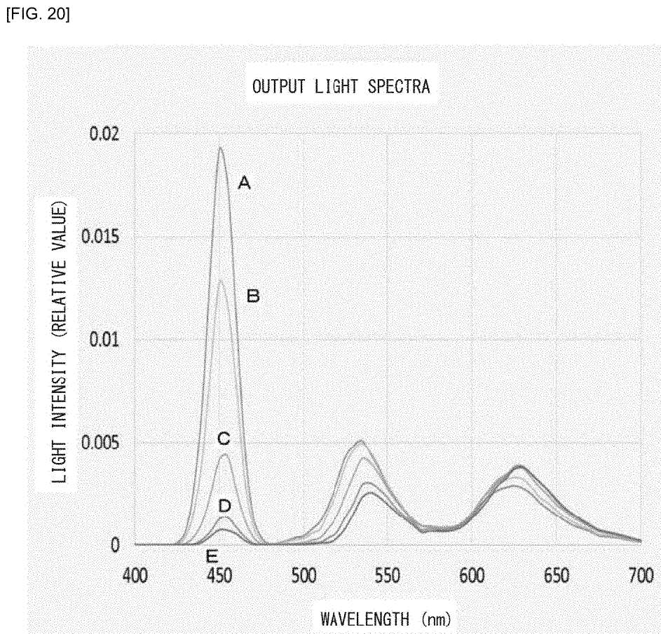

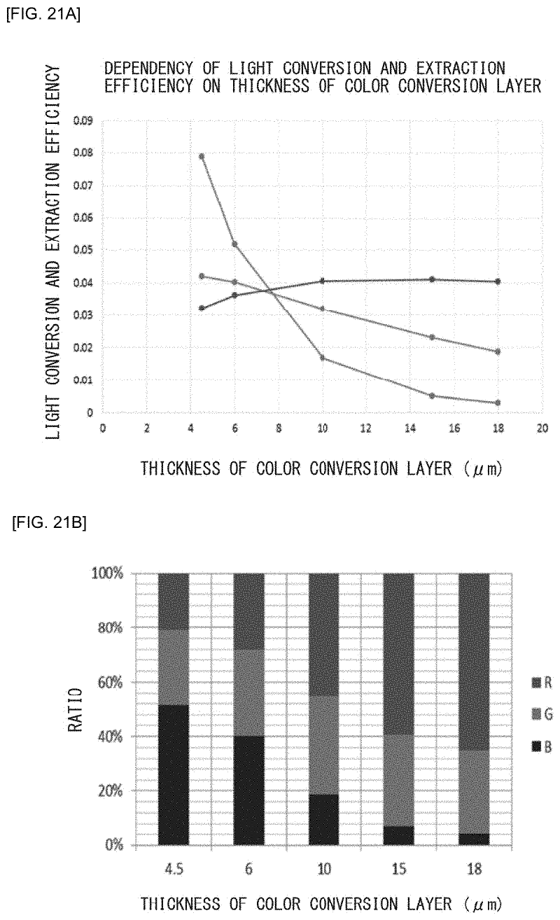

FIG. 20 illustrates the results of ray tracing simulation of the light emission spectra observed when the solution of mixture of the quantum dots G and the quantum dots R is changed in thickness. Further, FIG. 21A is a graph illustrating the light conversion and extraction efficiency of red light, green light, and blue light observed when the color conversion layer was changed in thickness. FIG. 21B is a graph illustrating the ratio between the amount of red light, the amount of green light, and the amount of blue light. In FIG. 20, “A” represents the result of the ray tracing simulation of the light emission spectrum observed when the thickness of the solution was 4.5 μm, “B” represents the results of the ray tracing simulation of the light emission spectrum observed when the thickness of the solution was 6.0 μm, “C” represents the results of the ray tracing simulation of the light emission spectrum observed when the thickness of the solution was 10 μm, “D” represents the results of the ray tracing simulation of the light emission spectrum observed when the thickness of the solution was 15 μm, and “E” represents the ray tracing simulation of the light emission spectrum observed when the thickness of the solution was 18 μm. Although the peaks of the light spectra partially overlap each other at a wavelength around 540 nm in FIG. 20, the highest peak (“A”) was observed when the thickness of the solution was 4.5 μm, the second highest peak (“B”) was observed when the thickness of the solution was 6.0 μm, the third highest peak (“C”) was observed when the thickness of the solution was 10 μm, the fourth highest peak (“D”) was observed when the thickness of the solution was 15 μm, and the lowest peak (“E”) was observed when the thickness of the solution was 18 μm. Also, although the peaks of the light spectra partially overlap each other at a wavelength around 630 nm in FIG. 20, the highest peaks (“C”, “D”, and “E”) were observed when the thickness of the solution was 10 μm, 15 μm and 18 μm, respectively, the second highest peak (“B”) was observed when the thickness of the solution was 6.0 μm, and the lowest peak (“A”) was observed when the thickness of the solution was 4.5 μm. The graph of FIG. 21A illustrates the integrated intensity obtained by integrating the light intensities of the red light, the green light, and the blue light in the results illustrated in FIG. 20. The graph of FIG. 21B illustrates the ratio between the amount of red light (indicated by an upper portion of the bar graph of FIG. 21B), the amount of green light (indicated by a middle portion of the bar graph of FIG. 21B), and the amount of blue light (indicated by a lower portion of the bar graph of FIG. 21B).

The following results may be derived from FIGS. 20, 21A, and 21B. That is, the amount of of blue light serving as excitation light emitted from the color conversion layer exponentially decreases as the thickness of the color conversion layer increases. The amount of green light emitted from the color conversion layer decreases as the effect of reabsorption of the quantum dots R increases with an increase in thickness of the color conversion layer. The amount of red light emitted from the color conversion layer monotonically increases as the thickness of the color conversion layer increases. It is apparent from these results that it is possible to adjust the ratio between the amount of red light, the amount of green light, and the amount of blue light by changing the thickness of the color conversion layer.

If the color conversion layer of the light emitting device emitting red light, the color conversion layer of the light emitting device emitting green light, and the color conversion layer of the light emitting device emitting blue light have the same thickness, the amount and type of the quantum dots included in the color conversion layers need to be adjusted to control the ratio between the amount of red light, the amount of green light, and the amount of blue light. This results in a loss of energy, except for the color extracted using the wavelength selection layer. However, according to the present disclosure, it is possible to increase the energy utilization efficiency simply by changing the thicknesses of the color conversion layers. Further, it is possible to reduce the manufacturing costs by eliminating the necessity to form (apply) different quantum dots for each light emitting device.

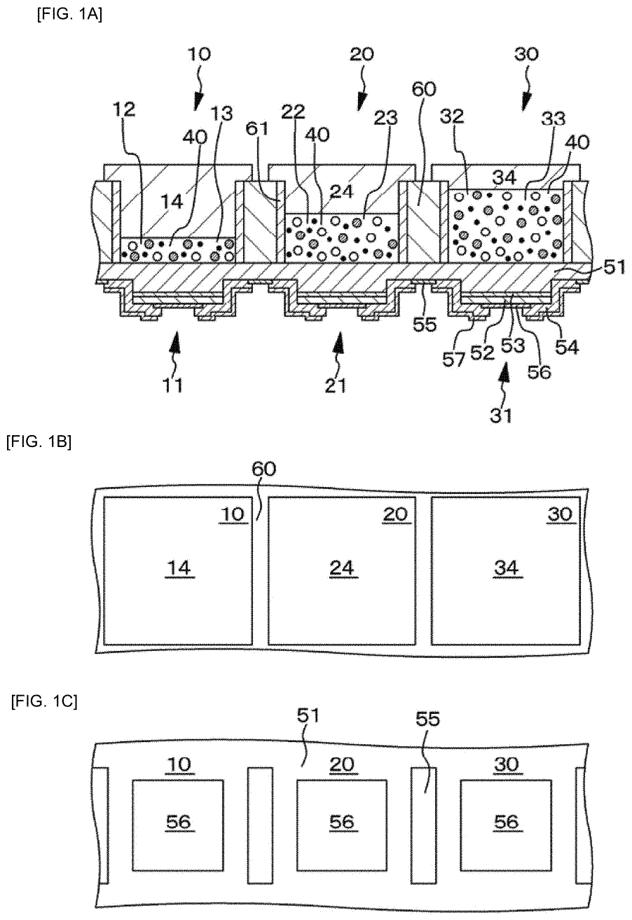

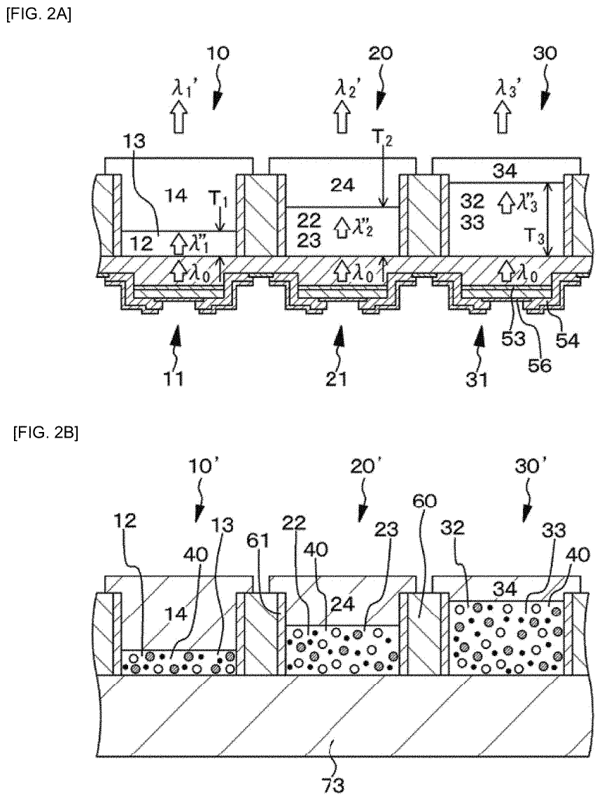

FIG. 1A is a schematic partial end view of the display apparatus and the light emitting device of Example 1. FIG. 1B schematically illustrates the arrangement of the wavelength selection layers. FIG. 1C schematically illustrates the arrangement of a first electrode and a second electrode. Further, FIG. 2A is a schematic partial end view of the display apparatus and the light emitting device of Example 1 in a different manner from FIG. 1A. FIG. 2B is a schematic partial end view of the light emitting member of Example 1. Note that one of the light emitting device units is illustrated in the schematic partial end view of the display apparatus.

The display apparatus of Example 1 includes

a plurality of light emitting device units each including a first light emitting device 10, a second light emitting device 20, and a third light emitting device 30, in which

the first light emitting device 10 includes

a first light generating unit 11 that generates light having a wavelength λ₀,

a first wavelength conversion layer 12 that includes a first color conversion layer 13 having a thickness T₁ and including a particulate color conversion material, the particulate color conversion material converting the color of the light having the wavelength λ₀ emitted from the first light generating unit 11, and

a first wavelength selection layer 14 that the light emitted from the first wavelength conversion layer 12 enters and that emits light having a wavelength λ₁′,

the second light emitting device 20 includes

a second light generating unit 21 that generates light having a wavelength λ₀,

a second wavelength conversion layer 22 that includes a second color conversion layer 23 having a thickness T₂ and including a particulate color conversion material, the particulate color conversion material converting the color of the light having the wavelength λ₀ emitted from the second light generating unit 21, and

a second wavelength selection layer 24 that the light emitted from the second wavelength conversion layer 22 enters and that emits light having a wavelength λ₂′,

the third light emitting device 30 includes

a third light generating unit 31 that generates light having a wavelength λ₀,

a third color conversion layer 32 that includes a third color conversion layer 33 having a thickness T₃ and including a particulate color conversion material, the particulate color conversion material converting the color of the light having the wavelength λ₀ emitted from the third light generating unit 31, and

a third wavelength selection layer 34 that the light emitted from the third wavelength conversion layer 32 enters and that emits light having a wavelength λ₃′ (where λ₁′<λ₂′<λ₃′ holds), and

T₁<T₂≤T₃ is satisfied.

Additionally, the light emitting device of Example 1 includes

light generating units 11, 21, and 31 that generate light having a wavelength λ₀, and

wavelength conversion layers 12, 22, and 32 that include color conversion layers 13, 23, or 33 including a particulate color conversion material, the particulate color conversion material converting the color of the light having the wavelength λ₀ emitted from the light generating units 11, 21, and 31, in which

the color conversion layers 12, 23, and 33 each have a thickness determined on the basis of the wavelength λ″ (where λ″>λ₀ holds) of light emitted from the wavelength conversion layers 12, 22, and 32.

Furthermore, a light emitting member (also referred to as a wavelength conversion member, a wavelength conversion sheet, or a quantum dot sheet) of Example 1 includes

a first light emitting portion 10′, a second light emitting portion 20′, and a third light emitting portion 30′, in which

the first light emitting portion 10′ includes a first wavelength conversion layer 12 including a first color conversion layer 13, the first color conversion layer 13 having a thickness T₁ and including a particulate color conversion material, the particulate color conversion material converting the color of light having a wavelength λ₀ emitted from a light generating unit,

the second light emitting portion 20′ includes a second wavelength conversion layer 22 including a second color conversion layer 23, the second color conversion layer 23 having a thickness T₂ and including a particulate color conversion material, the particulate color conversion material converting the color of light having a wavelength λ₀ emitted from a light generating unit,

the third light emitting portion 30′ includes the third wavelength conversion layer 32 including a third color conversion layer 33, the third color conversion layer 33 having a thickness T₃ and including a particulate color conversion material, the particulate color conversion material converting the color of light having a wavelength λ₀ emitted from a light generating unit,

T₁<T₂≤T₃ is satisfied, and

the peak wavelength λ₁₋ₚₑₐₖ″ of the light spectrum of the light emitted from the first wavelength conversion layer 12 is different from the peak wavelength λ₂₋ₚₑₐₖ″ of the light spectrum of light emitted from the second wavelength conversion layer 22 and the peak wavelength λ₃₋ₚₑₐₖ″ of the light spectrum of light emitted from the third wavelength conversion layer 32.

The light emitting member of Example 1 includes the first wavelength selection layer 14 provided on the first wavelength conversion layer 12, the second wavelength selection layer 24 provided on the second wavelength conversion layer 22, and the third wavelength selection layer 34 provided on the third wavelength conversion layer 32. Note that the first wavelength selection layer 14, the second wavelength selection layer 24, and the third wavelength selection layer 34 are not essential components. The light emitted from the first wavelength conversion layer 12 enters the first wavelength selection layer 14, and the first wavelength selection layer 14 emits light having a wavelength λ₁′. The light emitted from the second wavelength conversion layer 22 enters the second wavelength selection layer 24, and the second wavelength selection layer 24 emits light having a wavelength λ₂′. The light emitted from the third wavelength conversion layer 32 enters the third wavelength selection layer 34, and the third wavelength selection layer 34 emits light having a wavelength λ₃′ (where λ₁′<λ₂′<λ₃′ holds). Additionally, the light emitting member is provided on a transparent material member 73 described below. However, in some cases, the transparent material member 73 is unnecessary.

The light emitting device of Example 1 includes the particulate color conversion material including the first quantum dots and the second quantum dots. Further, the light emitting device of Example 1 includes the wavelength selection layers 14, 24, and 34 that the light emitted from the wavelength conversion layers 12, 22, and 32 enter.

The total thickness of the thickness of the wavelength conversion layer 12 (the color conversion layer 13) and the thickness of the wavelength selection layer 14 in the light emitting device 10, the total thickness of the thickness of the wavelength conversion layer 22 (the color conversion layer 23) and the thickness of the wavelength selection layer 24 in the light emitting device 20, and the total thickness of the thickness of the wavelength conversion layer 32 (the color conversion layer 33) and the thickness of the wavelength selection layer 34 in the light emitting device 30 are equal to each other. That is,

{the thickness of the first wavelength conversion layer 12 (the first color conversion layer 13)}+{the thickness of the first wavelength selection layer 14}={the thickness of the second wavelength conversion layer 22 (the second color conversion layer 23)}+{the thickness of the second wavelength selection layer 24}={the thickness of the third wavelength conversion layer 32 (the third color conversion layer 33)}+{the thickness of the third wavelength selection layer 34}

is satisfied within a range of ±10% thickness variation.

The particulate color conversion material in the light emitting devices 10, 20, and 30 in the display apparatus of Example 1 and the light emitting member of Example 1 includes the first quantum dots that convert light having a wavelengths λ₀ into light having a wavelengths λ₂″ (specifically, λ₂₋ₚₑₐₖ″) (where λ₂″>λ₀ holds), and the second quantum dots that convert light having a wavelengths λ₀ into light having a wavelengths λ₃″ (specifically, λ₃₋ₚₑₐₖ″) (where λ₃″>λ₂″>λ₀ holds). The second quantum dots further convert light having a wavelength λ₂″ (specifically, λ₂₋ₚₑₐₖ″) into light having a wavelength λ₃″ (specifically, λ₃₋ₚₑₐₖ″). Here, T₁<T₂<T₃ is satisfied. The thicknesses T₁, T₂, and T₃ preferably satisfy, but not limited to,

2≤T₂/T₁,

3≤T₃/T₁, and

1.5≤T₃/T₂, more preferably,

2≤T₂/T₁≤100,

3≤T₃/T₁≤100, and

1.5≤T₃/T₂≤10.

More specifically,

T₁=1 μm,

T₂=4 μm, and

T₃=12 μm

were satisfied. Further, the total thickness of the thickness of the wavelength conversion layer 12 (the color conversion layer 13) and the thickness of the wavelength selection layer 14, the total thickness of the thickness of the wavelength conversion layer 22 (the color conversion layer 23) and the thickness of the wavelength selection layer 24, and the total thickness of the thickness of the wavelength conversion layer 32 (the color conversion layer 33) and the thickness of the wavelength selection layer 34 were each 14 μm. Further,
the wavelength range (FWHM) of the wavelength λ₀=10 nm to 50 nm,
the wavelength range (FWHM) of the wavelength λ₁′=430 nm to 500 nm,
the wavelength range (FWHM) of the wavelength λ₂=500 nm to 570 nm,
the wavelength range (FWHM) of the wavelength λ₃′=610 nm to 750 nm,
the wavelength range (FWHM) of the wavelength λ₂″=500 nm to 570 nm,
the wavelength range (FWHM) of the wavelength λ₃″=610 nm to 750 nm,
the value of the wavelength λ₁₋ₚₑₐₖ′=460 nm,
the value of the wavelength λ₂₋ₚₑₐₖ′=530 nm,
the value of the wavelength λ₃₋ₚₑₐₖ′=630 nm,
the value of the wavelength λ₁₋ₚₑₐₖ″=460 nm,
the value of the wavelength λ₂₋ₚₑₐₖ″=530 nm, and
the value of the wavelength λ₃₋ₚₑₐₖ″=630 nm
were satisfied.

Further, the wavelength conversion layers 12, 22, and 32 include light scattering particles. Here, examples of the light scattering particles are SiO₂, Al₂O₃, and TiO₂.

The first quantum dot (quantum dot G) and the second quantum dot (quantum dot R) include an InP-based semiconductor material. Note that, in the drawings, the first quantum dot is indicated by a solid circle, the second quantum dot is indicated by a circle with hatching lines sloping from the upper right to the lower left, and the light scattering particle is indicated by a hollow circle. The first quantum dots, the second quantum dots, and the light scattering particle are embedded in a filler (matrix) 40 in the first color conversion layer 13, the second color conversion layer 23, and the third color conversion layer 33. To simplify the drawings, the filler 40 is not hatched in the drawings. Further, in Example 1, the first wavelength conversion layer 12 includes the first color conversion layer 13, the second wavelength conversion layer 22 includes the second color conversion layer 23, and the third wavelength conversion layer 32 includes the third color conversion layer 33. The wavelength selection layers 14, 24, and 34 each have a rectangular (square or rectangular) shape in plan view, as illustrated in FIG. 1B.

The first light generating unit 11, the second light generating unit 21, and the third light generating unit 31 that generate light having a wavelength λ₀ may have the same configuration or structure. Specifically, the light generating unit 11 of the light emitting device 10, the light generating unit 21 of the light emitting device 20, and the light generating unit 31 of the light emitting device 30 each include a light-emitting diode (LED). The LED desirably has a thickness of, but not limited to, 100 μm or less. The LED includes at least a first compound semiconductor layer 51, an active layer (light emitting layer) 53, and a second compound semiconductor layer 52 from the wavelength conversion layer side. The first compound semiconductor layer 51, the active layer 53, and the second compound semiconductor layer 52 are laminated into the laminated light emitting structure. The laminated light emitting structure includes, for example, a GaN-based compound semiconductor, specifically, a AlGaInN-based compound semiconductor having a known configuration or structure. To the first compound semiconductor layer 51, a first electrode 55 is coupled. Specifically, the first electrode 55 is formed on an exposed surface of the first compound semiconductor layer 51. To the second compound semiconductor layer 52, a first electrode 56 is coupled. Specifically, the second electrode 56 is formed on an exposed surface of the second compound semiconductor layer 52. The first compound semiconductor layer 51, the active layer 53, the second compound semiconductor layer 52, a part of the first electrode 55, and a part of the second electrode 56 are covered with an insulating layer 54 including SiO₂ or SiN. A light reflection film 57 is formed on a part of the region of the insulating layer 54. It is possible to prevent light generated in the active layer 53 from leaking to the outside by forming the light reflection film 57 including silver (Ag), gold (Au), aluminum (Al), or the like. Additionally, light generated in the active layer 53 is reflected from the light reflection film 57 and directed to the color conversion layers 13, 23, and 33. This improves the light extraction efficiency.

The first wavelength conversion layer 12 of the first light emitting device 10, the second wavelength conversion layer 22 of the second light emitting device 20, and the third wavelength conversion layer 32 of the third light emitting device 30 are separated from each other by a sidewall (partition wall) 60. The light reflection layer 61 is formed on an inner surface of the sidewall 60.

The first wavelength conversion layer 12 in the first light emitting device 10 emits mainly blue light based on blue light emitted from the first light generating unit 11. The blue light passes through the first wavelength selection layer 14 which passes blue light. As a result, blue light is emitted from the first light emitting device 10. The second wavelength conversion layer 22 in the second light emitting device 20 emits mainly green light and red light based on blue light emitted from the second light generating unit 21. The green light and the red light enter the second wavelength selection layer 24 which passes green light. As a result, green light is emitted from the second light emitting device 20. Further, the third wavelength conversion layer 32 in the third light emitting device 30 emits mainly red light based on blue light emitted from the third light generating unit 31. The red light passes through the third wavelength selection layer 34 that passes red light. As a result, red light is emitted from the third light emitting device 30.

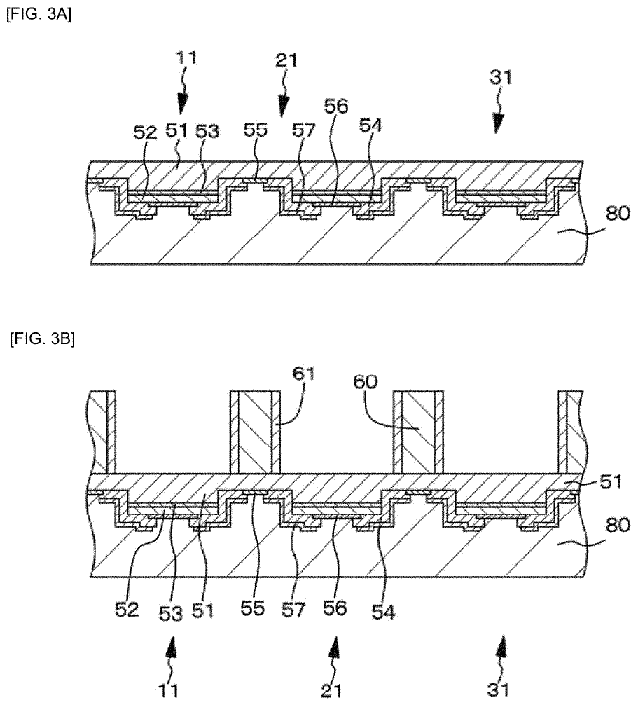

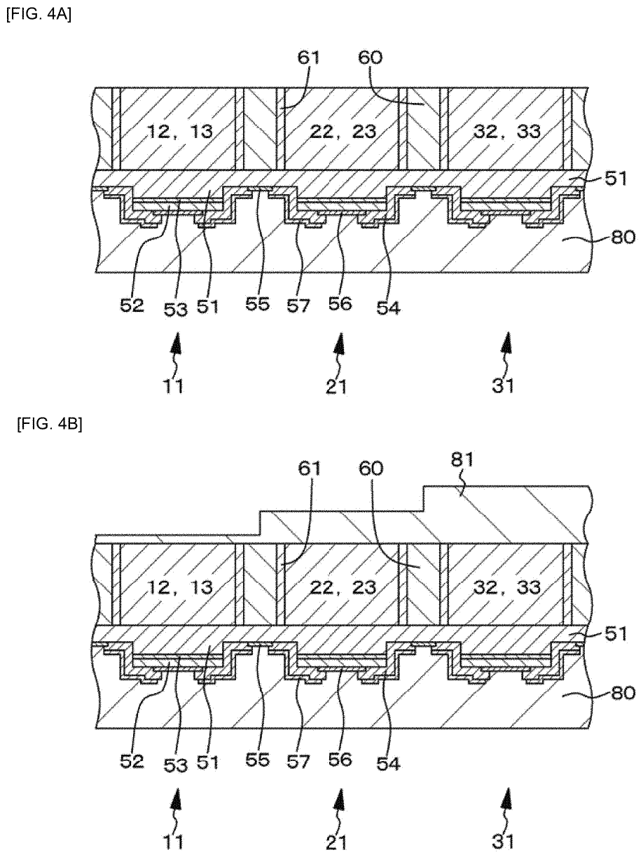

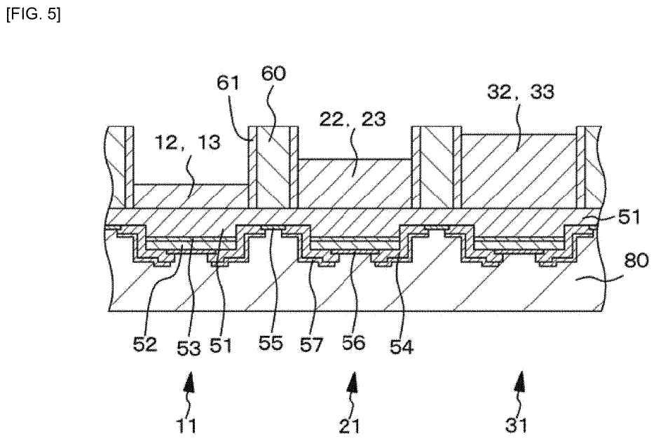

Hereinafter, an outline of the manufacturing process of the light emitting device of Example 1 is described with reference to FIG. 3A, FIG. 3B, FIG. 4A, FIG. 4B, and FIG. 5.

### [Step-100]

In the manufacture of the LEDs of the light generating units 11, 21, and 31, the first compound semiconductor layer 51 (including, for example, a buffer layer, an n-type contact layer, and an n-type cladding layer), the active layer (light emitting layer) 53, and the second compound semiconductor layer 52 (including, for example, a p-cladding layer and a p-contact layer) are laminated on a manufacturing base, which may be a sapphire base, by, for example, a MOCVD method. The manufacturing base is not limited to a sapphire base and may be, for example, an Si base or a GaN base. The laminated light emitting structure is then etched into a desired shape. Thereafter, an ohmic metal, such as Pd, or a transparent conductive material layer, such as ITO, is applied on the second compound semiconductor layer 52 by deposition, and shaped into a desired shape by a lift-off method. The second electrode 56 is thereby formed. Thereafter, the insulating layer 54 is formed on the laminated light emitting structure and the second electrode 56. The insulating layer 54 is then partially etched so that the first compound semiconductor layer 51 is exposed. Thereafter, the first electrode 55 including, for example, Ti/Pt/Au is formed on the exposed first compound semiconductor layer 51. Thereafter, the light reflection film 57 including silver (Ag) or aluminum (Al) is formed on a desired area of the insulating layer 54. The insulating layer 54 is then partially etched so that the second electrode 56 is exposed. Thereafter, the side of the light emitting device on which the second electrode 56 is formed is attached to a support base 80, which may be a sapphire base, for example. Thereafter, the manufacturing base is removed by a laser lift-off (LLO) method so that the first compound semiconductor layer 51 is exposed (see FIG. 3A).

### [Step-110]

Next, the sidewall 60 is formed in a desired region on the exposed first compound semiconductor layer 51. The sidewall 60 includes a resist material (e.g., a black resist material) that absorbs light. Thereafter, the light reflection layer 61 including Al or Ag is formed over the entire surface by a sputtering method, and the region of the light reflection layer 61 other than the side surface of the sidewall 60 is removed by dry etching. The light reflection layer 61 is thereby formed (see FIG. 3B).

### [Step-120]

Next, the region surrounded by the first compound semiconductor layer 51 and the light reflection layer 61 and in which the first light emitting device 10, the second light emitting device 20, and the third light emitting device 30 are to be formed is filled with a material obtained by dispersing the first quantum dots (quantum dots G), the second quantum dots (quantum dots R) and the light scattering particles in a filler including an ultraviolet curable resin (hereinafter, referred to as a “quantum dot dispersing material”) using a doctor blade. Thereafter, the quantum dot dispersing material is cured by irradiating with ultraviolet rays (see FIG. 4A). Note that the illustrations of the quantum dots and the light scattering particles are omitted in FIGS. 4A, 4B, and 5.

### [Step-130]

Thereafter, an ultraviolet curable resin material 81 for nanoimprinting is applied to the entire surface using a doctor blade. The ultraviolet curable resin material 81 is then cured while a template is pressed against the ultraviolet curable resin material 81, and thereafter, the template is removed. The ultraviolet curable resin material 81 is thereby formed into steps having thicknesses corresponding to the respective thicknesses of the color conversion layers 13, 23, and 33 (see FIG. 4B). Next, the entire surface is etched back to form the first color conversion layer 13 (having the thickness T₁), the second color conversion layer 23 (having the thickness T₂), and the third color conversion layer 33 (having the thickness T₃) having different thicknesses in the first light emitting device 10, the second light emitting device 20, and the third light emitting device 30 (see FIG. 5).

### [Step-140]

Next, the first wavelength selection layer 14, the second wavelength selection layer 24, and the third wavelength selection layer 34 are respectively formed on the first color conversion layer 13 in the first light emitting device 10, the second color conversion layer 23 in the second light emitting device 20, and the third color conversion layer 33 in the third light emitting device 30 by a known method. The total thickness of the thickness of the wavelength conversion layer 12 and the thickness of the wavelength selection layer 14, the total thickness of the thickness of the wavelength conversion layer 22 and the thickness of the wavelength selection layer 24, and the total thickness of the thickness of the wavelength conversion layer 32 and the thickness of the wavelength selection layer 34 are equal between the light emitting devices 10, 20, and 30. After a protective layer (not illustrated) is formed on the wavelength selection layers 14, 24, and 34, or after a protective glass plate (not illustrated) is attached to the wavelength selection layers 14, 24, and 34, the support base 80 is removed. The display apparatus having the structure illustrated in FIGS. 1A and 2A is thereby obtained.

The display apparatus, the light emitting device, and the light emitting member of Example 1 satisfy T₁<T₂≤T₃, more specifically, T₁<T₂<T₃. The compositions of the color conversion layers (the types, proportions, and the like of the first quantum dots and the second quantum dots in the color conversion layers) of the first light emitting device, the second light emitting device, and the third light emitting device may be the same. This improves the light utilization efficiency compared with a conventional technique using, for example, YAG phosphors. Moreover, although a conventional method of manufacturing the second light emitting device and the third light emitting device requires separately applying the quantum dots G and the quantum dots R by the ink-jet printing or the like, the separate application of the quantum dots is no longer required to manufacture the second light emitting device and the third light emitting device for the display apparatus, the light emitting device, and the light emitting member of Example 1. This reduces the manufacturing costs and the manufacturing processes. Further, the amount of unnecessary quantum dots to be removed is reduced compared with a conventional technique, enhancing the material utilization efficiency of the costly quantum dots. This also reduces the manufacturing cost. Furthermore, the light generating units are arranged in an individual manner, making it possible to achieve various pixel pitches. Such a structure is suitable for a display apparatus with a large screen. In a display apparatus in which a red light emitting LED, a green light emitting LED, and a blue light emitting LED are arranged, the red light emitting LED and the green light emitting LED has light emission efficiency lower than that of the blue light emitting LED. Thus, in Example 1, the blue light emitting LED having high light emission efficiency serves as an excitation light source, and the quantum dots having high light emission efficiency convert the wavelength. This enhances the light utilization efficiency.

### Example 2

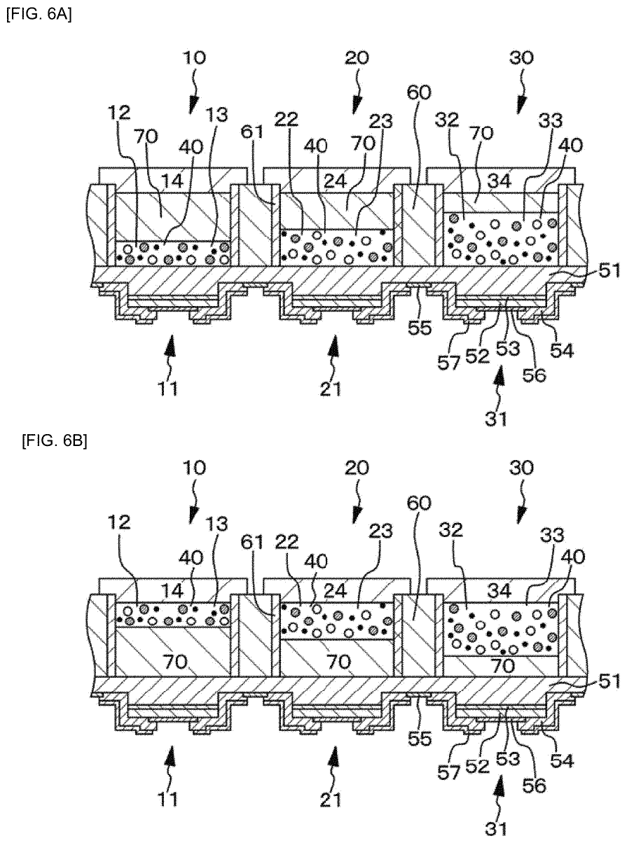

Example 2 is a modification of Example 1. FIGS. 6A and 6B are schematic partial end views of the display apparatus and the light emitting device of Example 2.

Note that the configuration or structure of the light emitting member of Example 2 or Examples 3 to 10 described below may be substantially the same as the configuration or structure of the light emitting device of the display apparatus of Example 1 or Examples 3 to 10 described below, except for having no light generating unit.

In Example 2, each of the wavelength conversion layers 12, 22, and 32 in the respective light emitting devices 10, 20, and 30 further includes a spacer layer 70 including an acrylic ultraviolet curable resin, an epoxy-based ultraviolet curable resin, a silicone-based thermosetting resin, or an epoxy-based thermosetting resin.

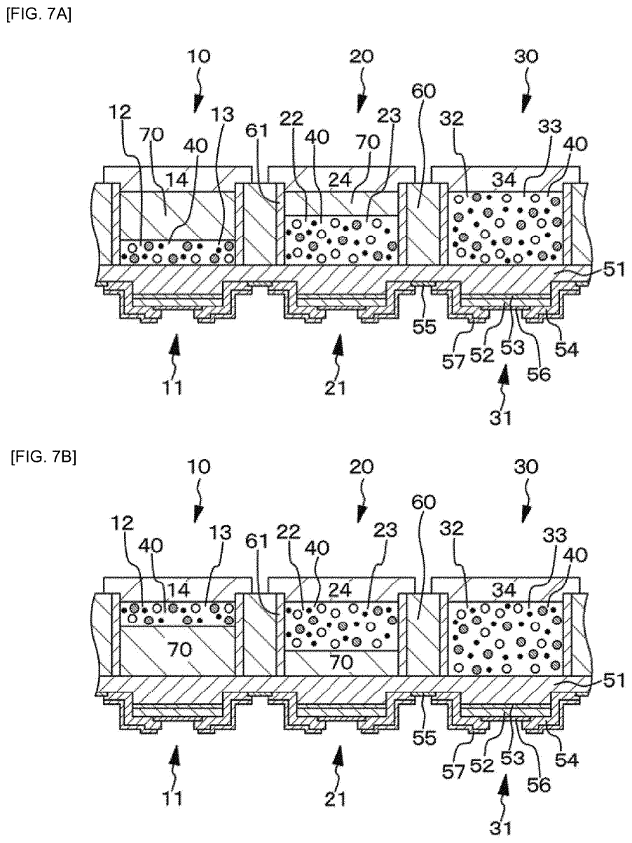

The total thickness of the thickness of the spacer layer 70 and the thicknesses of the color conversion layer 13 in the light emitting device 10, the total thickness of the thickness of the spacer layer 70 and the thickness of the color conversion layer 23 in the light emitting device 20, and the total thickness of the thickness of the spacer layer 70 and the thickness of the color conversion layer 33 in the light emitting device 30 are equal to each other. The spacer layer 70 may be positioned on a light emitting side of the color conversion layer 13, 23, or 33 (see FIG. 6A), or a light incident side of the color conversion layer 13, 23, or 33 (see FIG. 6B). In some cases, the third light emitting device 30 may be provided with no spacer as illustrated in the schematic partial end views of FIGS. 7A and 7B.

Except for the above points, the configuration or structure of the display apparatus and the light emitting device of Example 2 may be the same as the configuration or structure of the display apparatus and the light emitting device of Example 1, and thus detailed descriptions thereof are omitted.

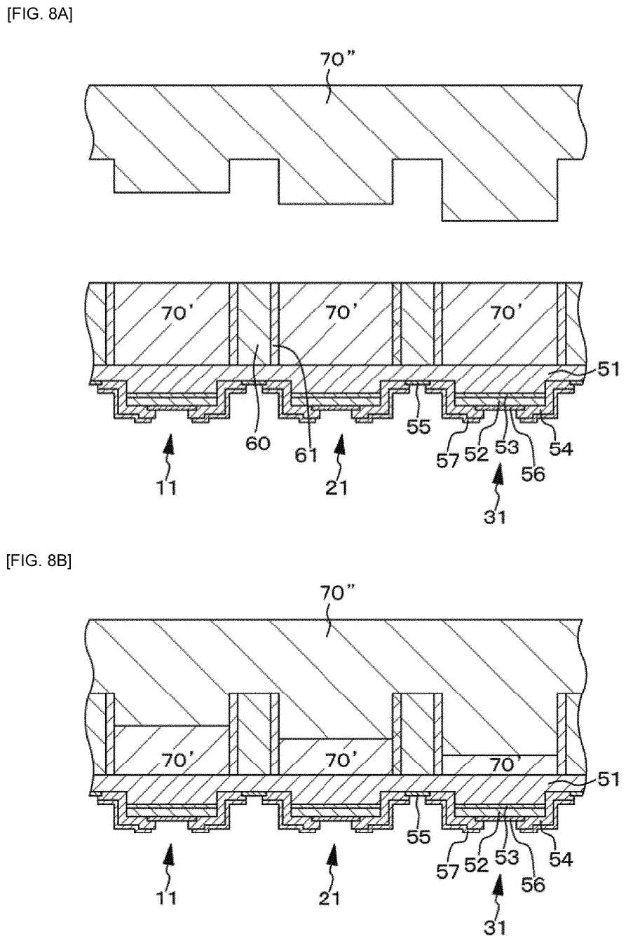

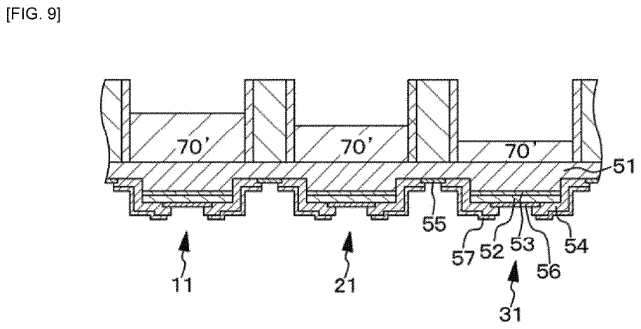

In the manufacture of the display apparatus of Example 2 illustrated in FIG. 6B, a template 70″ is prepared (see FIG. 8A), and a spacer forming layer 70′ including an ultraviolet curable resin for nanoimprinting is applied to the entire surface by a doctor blade method in between [Step-110] and [Step-120]. The spacer forming layer 70′ is thereby formed into steps having respective thicknesses corresponding to the thicknesses of the color conversion layer 13 in the light emitting device 10, the color conversion layer 23 in the light emitting device 20, and the color conversion layer 33 in the light emitting device 30 using the template 70″ (see FIG. 8B). The spacer forming layer 70′ is then cured by ultraviolet rays, and thereafter the template 70″ is removed. The structure illustrated in FIG. 9 is thereby obtained. Thereafter, steps following [Step-120] of Example 1 are performed.

In Example 1, a portion of the quantum dot dispersion material accumulated to the height of the sidewall 60 in [Step-120] is removed by dry etching in [Step-130]. Thus, the removed quantum dot dispersion material results in material loss. In contrast, in Example 2, using the spacer layer 70 reduces the amount of the quantum dot dispersion material to be charged. As a result, the material utilization efficiency is increased. Further, the color conversion layers 13, 23, and 33 may be positioned farther from the light generating units 11, 21, and 31 in Example 2 than in Example 1. This mitigate the influence of heat generation in the light generating units 11, 21, and 31 on the color conversion layers 13, 23, and 33. Furthermore, the color conversion layers 13, 23, and 33 serving as underlayers of the wavelength selection layers 14, 24, and 34 may be made into the same height. This improves the applicability of the wavelength selection layers 14, 24, and 34 compared with Example 1.

### Example 3

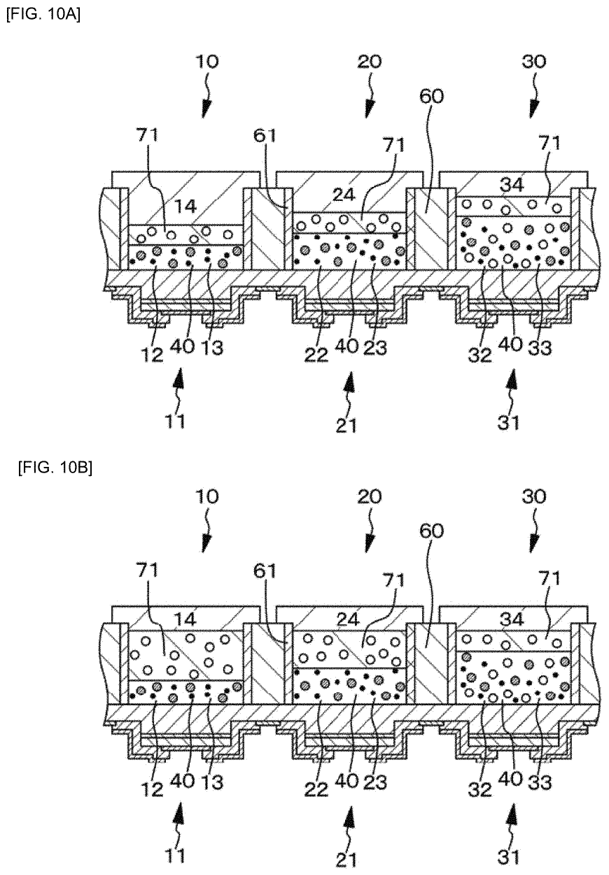

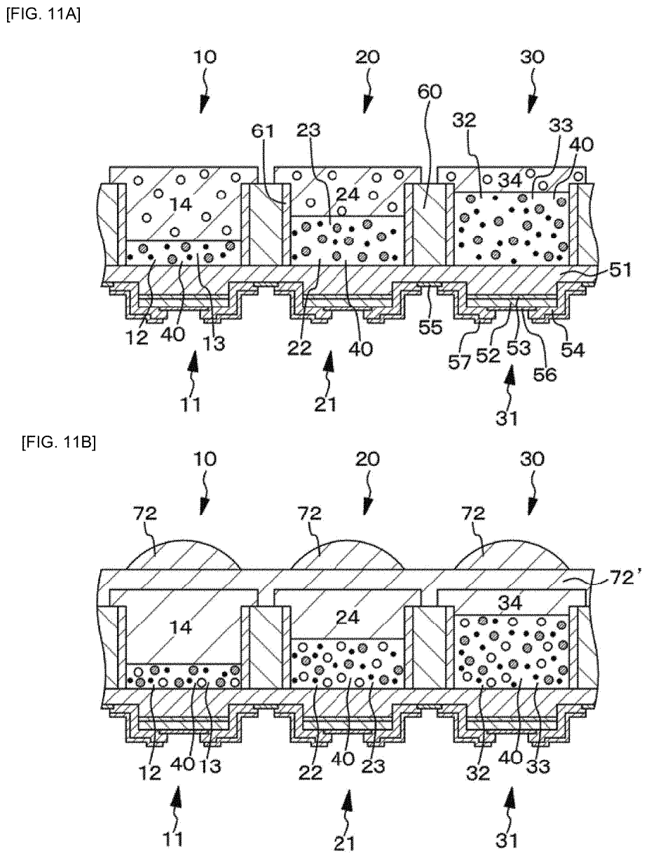

Example 3 is a modification of Examples 1 and 2. FIGS. 10A, 10, and 11A are schematic partial end views of the display apparatus and the light emitting device of Example 3. The wavelength conversion layers 12, 22, and 32 in the light emitting devices 10, 20, and 30 each further include a light-scattering particle layer 71. Note that Example 3 illustrated in FIG. 10A, Modification Example-1 of Example 3 illustrated in FIG. 10B, and Modification Example-2 of Example 3 illustrated in FIG. 11A are modification examples of Example 1. In the structure illustrated in FIG. 10B, the total thickness of the thickness of the light-scattering particle layer 71 and the thickness of the color conversion layer 13 in the light emitting device 10, the total thickness of the thickness of the light-scattering particle layer 71 and the thickness of the color conversion layer 23 in the light emitting device 20, and the total thickness of the thickness of the light-scattering particle layer 71 and the thickness of the color conversion layer 33 in the light emitting device 30 are equal to each other. The light-scattering particle layer 71 is positioned on the light emitting side of the color conversion layer 13, 23, or 33. The light-scattering particle layer 71 is formed by dispersing light scattering particles in an ultraviolet curable resin. Alternatively, the light scattering particles are included in the wavelength selection layers 14, 24, and 34, as in the schematic partial end view of the modification of the display apparatus and the light emitting device of Example 3 illustrated in FIG. 11A.

Note that, unlike in Example 1, the light scattering particles are not included in the color conversion layers 13, 23, and 33 in the modifications of Example 1 illustrated in FIGS. 10A, 10B, and 11A. As described above, the wavelength conversion layers 12, 22, and 32 each have the light-scattering particle layer 71, or the wavelength selection layers 14, 24, and 34 include the light scattering particles. This increases the amount of quantum dots to be charged in the color conversion layers 13, 23, and 33 having the respective desired thicknesses T₁, T₂, and T₃. If a small amount of the quantum dots is charged in the color conversion layers 13, 23, and 33, the absorption coefficient a decreases. To obtain the same light absorption rate A using the above equation (1), it is necessary to increase the thicknesses of the color conversion layers 13, 23, and 33. However, in Example 3, it is possible to increase the amount of quantum dots to be charged in the color conversion layers 13, 23, and 33. This allows the thicknesses T₁, T₂, and T₃ to be thinner, reducing the amount of quantum dots to be used.

Except for the above points, the configuration or structure of the display apparatus and the light emitting device of Example 3 may be the same as the configurations or structures of the display apparatuses and the light emitting devices of Examples 1 and 2, and thus detailed descriptions thereof are omitted.

### Example 4

Example 4 is a modification of Examples 1 to 3. FIG. 11B is a schematic partial end view of the display apparatus and the light emitting device of Example 4. In each of the light emitting devices 10, 20, and 30, an on-chip micro-lens 72 having a known configuration or structure is provided on the light emitting side of the wavelength selection layers 14, 24, or 34. The on-chip micro-lens 72 may include resin or glass. Specifically, for example, a planarizing layer 72′ is formed on the light emitting side of the wavelength selection layer 14, 24, or 34, and an on-chip micro-lens formation layer is formed on the planarizing layer 72′. Then, a resist layer is formed on the on-chip micro-lens formation layer, and the resist layer is patterned. The resist layer is then heated to have a shape similar to that of an on-chip micro-lens. Thereafter, the resist layer and the on-chip micro-lens formation layer are etched back to form an on-chip micro-lens. Alternatively, the on-chip micro-lens may be formed by melting the resist material by thermal reflow and using the surface tension of the resist material. Alternatively, the on-chip micro-lens may be obtained by a combination of a photolithography technique and an an etching method using a gray-tone mask, or may be obtained by forming a transparent resin material into a lens shape by a nanoimprinting method. Still alternatively, the on-chip micro-lens 72 may be attached by a known method. The quantum dots emit light isotopically. Thus, the light emitted from the wavelength selection layers 14, 24, and 34 into the air is in the Lambertian light distribution state or has distribution characteristics similar to the Lambertian light distribution state. Meanwhile, the structure of Example 4 may be applied to focus light into a narrow angle in front. This makes it possible to increase the light utilization efficiency.

Except for the above points, the configuration or structure of the display apparatus and the light emitting device of Example 4 may be the same as the configurations or structures of the display apparatuses and the light emitting devices of Examples 1 to 3, and thus detailed descriptions thereof are omitted.

### Example 5

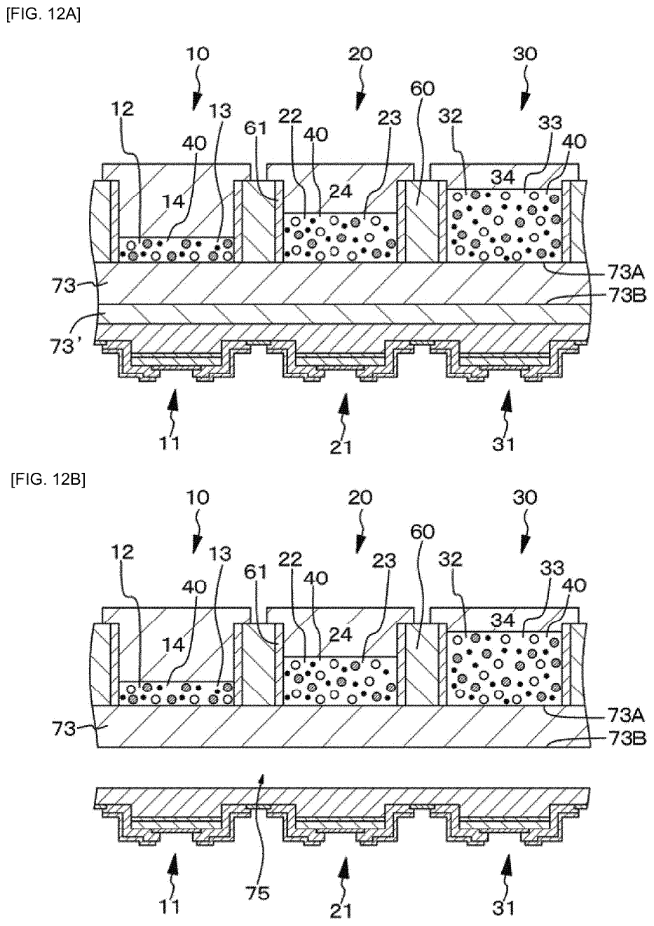

Example 5 is a modification of Examples 1 to 4. FIG. 12A illustrates a schematic partial end view of the display apparatus, the light emitting device, and the light emitting member of Example 5. In the light emitting devices 10, 20, and 30, a transparent material member 73 is disposed between the light generating units 11, 21, and 31 and the wavelength conversion layers 12, 22, and 32. The transparent material member 73 includes plastic, such as polyethylene terephthalate (PET) or polycarbonate, glass, sapphire, or the like. Specifically, the wavelength conversion layers 12, 22, and 32 and the wavelength selection layers 14, 24, and 34 are provided on a first surface 73A of the transparent material member 73. A second surface 73B of the transparent material member 73 opposite to the first surface 73A is attached to the light generating units 11, 21, and 31 with an adhesive layer 73′ interposed therebetween. Note that the structure in which the first wavelength conversion layer 12, the second wavelength conversion layer 22, and the third wavelength conversion layer 32 are formed on the transparent material member 73 corresponds to the light emitting member. Examples of the material of the adhesive layer may include thermosetting adhesives, such as an acrylic-based adhesive, an epoxy-based adhesive, an urethane-based adhesive, a silicone-based adhesive, and a cyanoacrylate-based adhesive, and ultraviolet-curable adhesives.

Specifically, the wavelength conversion layers 12, 22, and 32 and the wavelength selection layers 14, 24, and 34 are formed on the first surface 73A of the transparent material member 73 attached to a first support base through the same steps as [Step-110] to [Step-130] of Example 1. Thereafter, the wavelength selection layers 14, 24, and 34 are attached to a second support base, and the first support base is then removed. Thereafter, the exposed second surface 73B of the transparent material member 73 is attached to the light generating units 11, 21, and 31 with the adhesive layer 73′ interposed therebetween. As described above, the light generating units 11, 21, and 31, the wavelength conversion layers 12, 22, and 32, and the wavelength selection layers 14, 24, and 34 (i.e., the light emitting members) are separately manufactured before being attached. This improves the production yield.

Alternatively, as in the schematic partial end view of Modification Example-1 of Example 5 illustrated in FIG. 12B, the transparent material member 73 may be provided between the light generating units 11, 21, and 31 and the wavelength conversion layers 12, 22, and 32, and a space (gap) 75 may be provided between the transparent material member 73 and the light generating units 11, 21, and 31. Specifically, a support portion (not illustrated) may be provided on the light generating unit side, and the second surface 73B of the transparent material member 73 may be attached to the support portion.

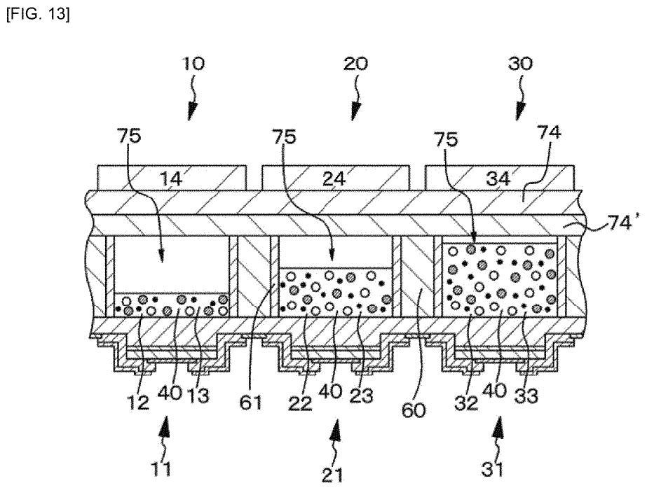

Alternatively, as in the schematic partial end view of Modification Example-2 of Example 5 illustrate in a FIG. 13, a transparent material member 74 is provided between the wavelength conversion layers 12, 22, and 32 and the wavelength selection layers 14, 24, and 34 in the light emitting devices 10, 20, and 30. Further, the space (gap) 75 is provided between the wavelength conversion layers 12, 22, and 32 and the wavelength selection layers 14, 24, and 34 (specifically, the transparent material member 74).

Specifically, the wavelength selection layers 14, 24, and 34 are formed on a support base. Thereafter, the transparent material member 74 is attached to the light generating units 11, 21, and 31 and the wavelength conversion layers 12, 22, and 32 (specifically, to the top surface of the sidewall 60) with an adhesive layer 74′ interposed therebetween. Alternatively, a support portion is provided on the wavelength selection layer side, and the transparent material member 74 is attached to the support portion. The support base may be removed or left as a protective member. As described above, the light generating units 11, 21, and 31, the wavelength conversion layers 12, 22, and 32, and the wavelength selection layers 14, 24, and 34 (the light emitting members) are separately manufactured before being attached. This improves the production yield. The wavelength conversion layers 12, 22, and 32 may be attached to the wavelength selection layers 14, 24, and 34 (specifically, the transparent material member 74) such that the space (gap) 75 is formed therebetween. Providing the space (gap) 75 allows a portion of the light emitted from the wavelength conversion layers 12, 22, and 32 to be totally reflected on the surfaces of the wavelength conversion layers 12, 22, and 32 exposed to the space. This reduces the light emitted from the wavelength selection layers 14, 24, and 34 and totally reflected on the protective member (e.g., a protective glass plate) provided on the wavelength selection layers 14, 24, and 34, enhancing the light extraction efficiency.

Except for the above points, the configuration or structure of the display apparatus and the light emitting device of Example 5 may be the same as the configurations or structures of the display apparatuses and the light emitting devices of Examples 1 to 4, and thus detailed descriptions thereof are omitted.

### Example 6

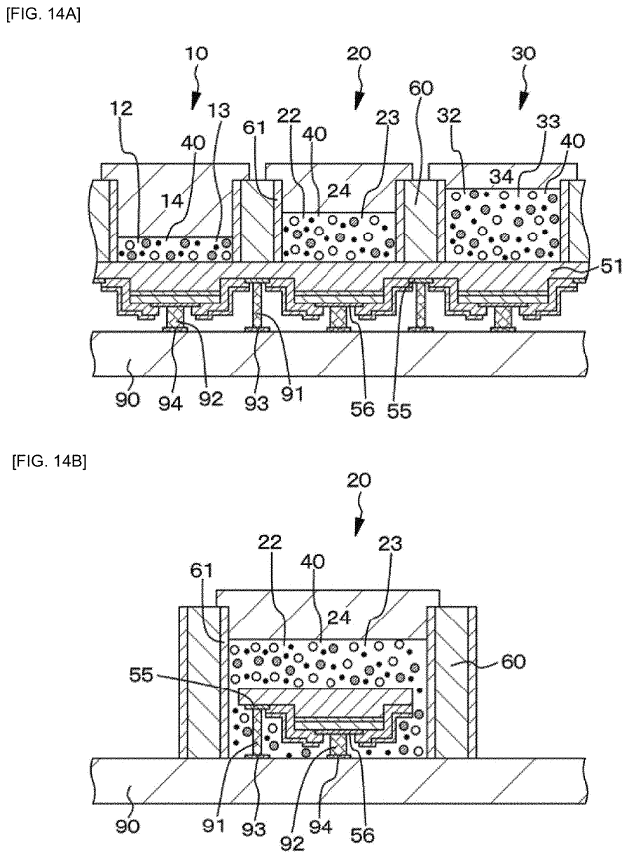

Example 6 is a modification of Examples 1 to 5. FIG. 14A illustrates the schematic partial end view of the display apparatus of Example 6. In Example 6, the light generating units 11, 21, and 31 of the respective light emitting devices 10, 20, and 30 are coupled to drive circuitry (not illustrated) provided on a base 90. The light generating units 11, 21, and 31 may be coupled to the drive circuitry provided on the base 90 by a method using a bump including solder, indium, gold (Au) or the like, a chip-on-chip method, a method using a through-chip via (TCV) or a through-silicon via (TSV), or a metal-metal junction, such as Cu—Cu junction. The base may be, for example, a silicon semiconductor base, a glass base, a GaN base, or a SiC base. The drive circuitry is, for example, a CMOS circuit provided on the base 90, which may be a silicon semiconductor base. Alternatively, the drive circuitry is, for example, a TFT circuit provided on the base 90, which may be a glass base. Coupling portions 93 and 94 coupled to the drive circuitry are provided on a surface of the base 90. The coupling portions 93 and 94 are coupled to the first electrode 55 and the second electrode 56 via bumps 91 and 92 including gold, for example. In the display apparatus of Example 6, the light emitting devices 10, 20, and 30 and the drive circuitry are integrated. Accordingly, it is possible to reduce the size of the display apparatus. Further, as in the schematic partial end view illustrated in FIG. 14B, it is possible to suppress the occurrence of optical crosstalk between the light emitting devices adjacent to each other by employing the structure in which the light generating units 11, 21, and 31 are surrounded by the sidewall (partition wall) 60. Note that, although the second light emitting device is illustrated in FIG. 14B, the first light emitting device 10 and the third light emitting device 30 have similar configurations or structures. It is also to be noted that the light emitting devices having such configurations may be obtained by performing the same step as [Step-100] of Example 1, attaching the light generating units 11, 21, and 31 to the base 90 on which the drive circuitry is provided, and then performing the same steps as [Step-110] to [Step-140] of Example 1.

Except for the above points, the configuration or structure of the display apparatus and the light emitting device of Example 6 may be the same as the configurations or the structures of the display apparatuses and the light emitting devices of Examples 1 to 5, and thus detailed descriptions thereof are omitted.

### Example 7

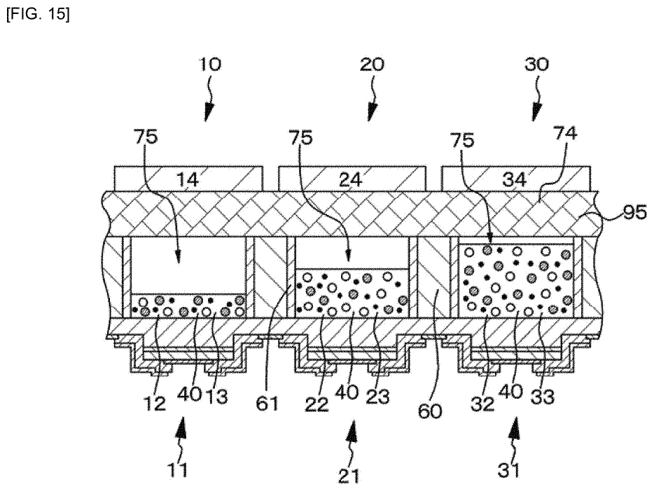

Example 7 is a modification of Examples 1 to 6. FIG. 15 illustrates a schematic partial end view of the display apparatus of Example 7. In Example 7, a light shutter means 95 is provided between the wavelength conversion layers 12, 22, and 32 and the wavelength selection layers 14, 24, and 34 in the light emitting devices. The light shutter means 95 may be, for example, a liquid crystal display of a transmission type. Providing the light shutter means 95 makes it possible to display an image with a higher contrast and higher image quality and to block external light while the display apparatus is in a non-luminous state. This enhances the contrast of external light. The light shutter means 95 may be operated in conjunction with the operations of the light generating units 11, 21, and 31.

Except for the above points, the configuration or structure of the display apparatus and the light emitting device of Example 7 may be the same as the configurations or structures of the display apparatuses and the light emitting devices of Examples 1 to 6, and thus detailed descriptions are omitted.

### Example 8

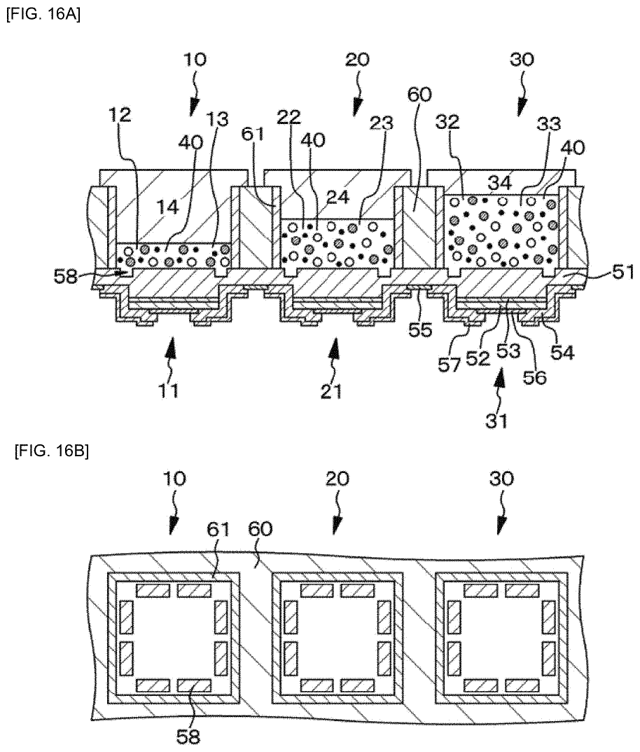

Example 8 is a modification of Examples 1 to 7. In the display apparatuses of Examples 1 to 7, the first compound semiconductor layer 51 in the light generating unit 11, 21, or 31 is coupled to the adjacent light generating unit. Thus, light generated in the light generating units 11, 21, and 31 and light emitted from the color conversion layers 13, 23, and 33 propagate to the adjacent light emitting device through the first compound semiconductor layer 51. This can reduce the light extraction efficiency and cause optical crosstalk. To address this, as in the schematic partial end view illustrated in FIG. 16A and the schematic arrangement of the sidewall 60, the light reflection layer 61, and the cutouts 58 illustrated in FIG. 16B, the display apparatus of Example 8 includes cutouts 58. The cutout 58 is formed by partially cutting out the first compound semiconductor layer 51 in a boundary region between the adjacent light emitting devices or a region in the vicinity of the boundary region. Note that, in FIG. 16B, the sidewall 60, the light reflection layer 61, and the cutouts 58 are hatched to distinguish them. The wavelength conversion layers 12, 22, and 32 extend in the cutouts 58. Current injection into the first compound semiconductor layer 51 is still not prevented by providing the cutouts 58. In the modification of Example 6 illustrated in FIG. 14B described above, the bottom of the sidewall (partition wall) 60 extends through the boundary region between the light emitting devices. Employing these structures makes it possible to improve the light extraction efficiency and prevent the occurrence of optical crosstalk.

Except for the above points, the configuration or structure of the display apparatus and the light emitting device of Example 8 may be the same as the configurations or structures of the display apparatuses and the light emitting devices of Examples 1 to 7, and thus detailed descriptions thereof are omitted.

### Example 9

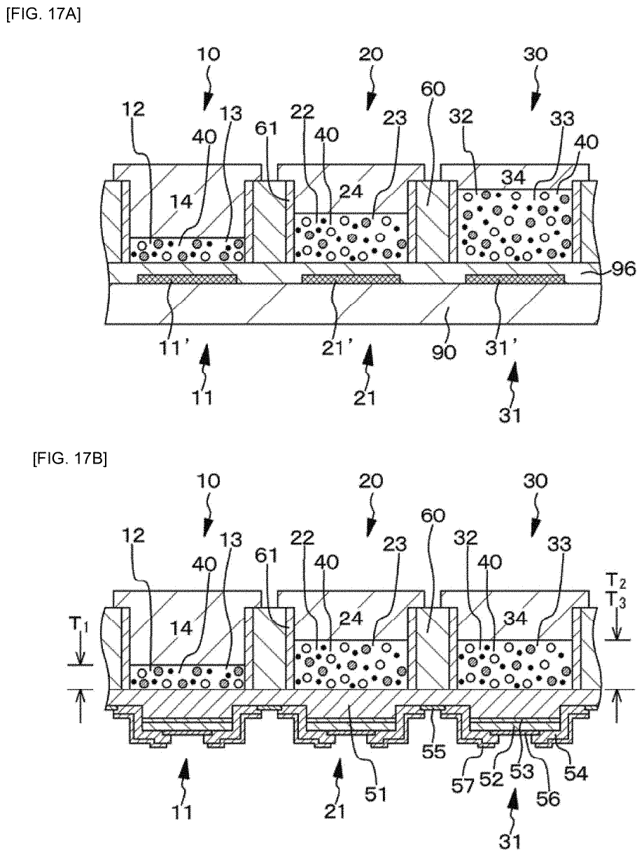

Example 9 is a modification of Examples 1 to 8. FIG. 17 is a schematic partial cross-sectional view of the display apparatus of Example 9. In Example 9, the light generating units 11′, 21′, and 31′ of the respective light emitting devices are organic electroluminescent elements (organic EL elements) having known configurations or structures. The light generating units 11′, 21′, and 31′ are provided on the base 90 on which drive circuitry (not illustrated) for driving the light generating units 11′, 21′, and 31′ is provided. The light generating units 11′, 21′, and 31′ are covered with an insulating film 96. The wavelength conversion layers 12, 22, and 32 are formed on the insulating film 96. The light generating units 11′, 21′, and 31′ emit blue light.

Except for the above points, the configuration or structure of the display apparatus and the light emitting device of Example 9 may be the same as the configurations or structures of the display apparatuses and the light emitting devices of Examples 1 to 8, and thus detailed descriptions thereof are omitted.

### Example 10

Example 10 is a modification of Examples 1 to 9. FIG. 17B is a schematic partial end view of the display apparatus of Example 10. In Example 10, the particulate color conversion material in each light emitting device includes the first quantum dots and the second quantum dots, and T₁<T₂=T₃ is satisfied. Here, it is preferable that the thicknesses T₁, T₂ and T₃ satisfy the relation represented by, but not limited to,

1≤(T₂=T₃)/T₁, more preferably,

1≤(T₂=T₃)/T₁≤100.

### Specifically,

T₁=1 μm, and

T₂=T₃=8 μm

are satisfied.

As illustrated in FIG. 21B, when the thickness T₂ and the thickness T₃ increase to some extent, it is possible for the mixed system of the first quantum dots and the second quantum dots to emit green light and red light while suppressing emission of blue light. Accordingly, the first wavelength conversion layer 12 in the first light emitting device 10 mainly emits blue light based on blue light emitted from the first light generating unit 11, and the blue light passes through the first wavelength selection layer 14 that passes blue light. As a result, blue light is emitted from the first light emitting device 10. Further, the second wavelength conversion layer 22 in the second light emitting device 20 mainly emits green light and red light based on blue light emitted from the second light generating unit 21, and the green light and the red light enter the wavelength selection layer 24 that passes green light. As a result, green light is emitted from the second light emitting device 20. Further, the third wavelength conversion layer 32 in the third light emitting device 30 mainly emits green light and red light based on the blue light emitted from the third light generating unit 31, and the green light and the red light enter the third wavelength selection layer 34 that passes red light. As a result, red light is emitted from the third light emitting device 30.

Except for the above points, the configuration or structure of the display apparatus and the light emitting device of Example 10 may be the same as the configurations or structures of the display apparatuses and the light emitting devices of Examples 1 to 9, and thus detailed descriptions thereof are omitted.

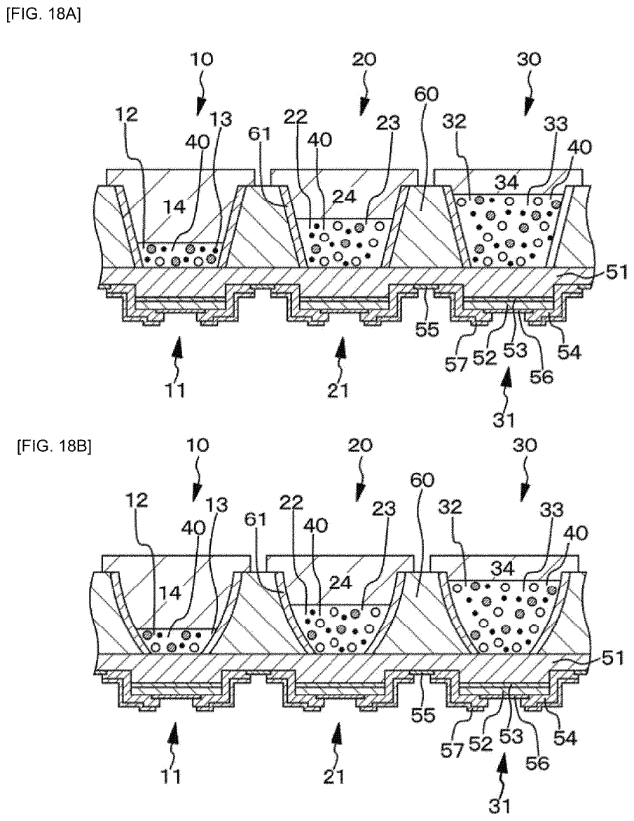

While the present disclosure has been described above with reference to the preferred examples, the present disclosure is not limited to these examples. The configurations or structures of the light generating units 11, 21, and 31, the configurations or structures of the wavelength conversion layers 12, 22, and 32, the configurations or structures of the wavelength selection layers 14, 24, and 34, the configuration or structure of the light shutter means 95, and the connection between the light generating units 11, 21, and 31 and the drive circuitry described in the examples are mere examples and may be changed as appropriate. Although the wavelength selection layers 14, 24, and 34 each have a rectangular (square or rectangular) shape in plan view, as illustrated in FIG. 1B in the examples, the planar shape of the wavelength selection layers 14, 24, and 34 are not limited thereto. Alternatively, the wavelength selection layers 14, 24, and 34 may each have a circular shape, an elliptical shape, an oval shape, or a polygonal (e.g., hexagonal) shape. Essentially, the light emitting devices may be arranged into any desired array, such as a stripe array, a diagonal array, a delta array, a rectangle array, or a bayer array. The first light emitting device, the second light emitting device, and the third light emitting device may be changed in size (the areas of the light emitting regions of the light emitting devices). Further, although the sidewall (partition wall) 60 is upright with respect to the light generating unit 11, 21, or 31 in the above examples, this is a non-limiting example. As in the schematic partial end view illustrated in FIG. 18A, the sidewall 60 may have a tapered shape expanding from the bottom to the top of the wavelength conversion layer 12, 22, or 32. Alternatively, as in the schematic partial end view illustrated in FIG. 18B, the sidewall 60 may have a curved shape (bowl shape) expanding from the bottom to the top of the wavelength conversion layer 12, 22, or 32. Note that, in that case, the wavelength selection layers 14, 24, and 34 each have a circular shape in plan view. Accordingly, it is possible to increase the front luminance of the display apparatus by employing these shapes.

It is to be noted that the present disclosure may also have the following configurations.

### <<Display Apparatus>>

A display apparatus including

a plurality of light emitting device units each including a first light emitting device,

a second light emitting device, and a third light emitting device, in which

the first light emitting device includes

a first light generating unit that generates light having a wavelength λ₀,

a first wavelength conversion layer that includes a first color conversion layer having a thickness T₁ and including a particulate color conversion material, the particulate color conversion material converting the color of the light having the wavelength λ₀ emitted from the first light generating unit, and

a first wavelength selection layer that the light emitted from the first wavelength conversion layer enters and that emits light having a wavelength λ₁′,

the second light emitting device includes

a second light generating unit that generates light having a wavelength λ₀,

a second wavelength conversion layer that includes a second color conversion layer having a thickness T₂ and including a particulate color conversion material, the particulate color conversion material converting the color of the light having the wavelength λ₀ emitted from the second light generating unit, and

a second wavelength selection layer that the light emitted from the second wavelength conversion layer enters and that emits light having a wavelength λ₂′,

the third light emitting device includes

a third light generating unit that generates light having a wavelength λ₀,

a third color conversion layer that includes a third color conversion layer having a thickness T₃ and including a particulate color conversion material, the particulate color conversion material converting the color of the light having the wavelength λ₀ emitted from the third light generating unit, and

a third wavelength selection layer that the light emitted from the third wavelength conversion layer enters and that emits light having a wavelength λ₃′ (where λ1′<λ2′<λ3′ holds), and

T₁<T₂≤T₃ is satisfied.
[A02] The display apparatus according to [A01], in which the particulate color conversion material in each of the light emitting devices includes a first quantum dot that converts light having a wavelength λ₀ into light having a wavelength λ₂″ (where λ₂″>λ₀ holds) and a second quantum dot that converts light having a wavelength λ₀ into light having a wavelength λ₃″ (where λ₃″>λ₂″>λ₀ holds).
[A03] The display apparatus according to [A02], in which the second quantum dot further converts light having a wavelength λ₂″ into light having a wavelength λ₃″.
[A04] The display apparatus according to [A02] or [A03], satisfying T₁<T₂=T₃.
[A05] The display apparatus according to [A02] or [A03], satisfying T₁<T₂<T₃.
[A06] The display apparatus according to any one of [A01] to [A05], in which the wavelength conversion layer in each of the light emitting devices further includes a spacer layer, and

the total thickness of the thickness of the spacer layer and the thickness of the color conversion layer is equal between the light emitting devices.
[A07] The display apparatus according to [A06], in which the spacer layer is positioned on a light incident side of the color conversion layer.
[A08] The display apparatus according to [A06], in which the spacer layer is positioned on a light emitting side of the color conversion layer.
[A09] The display apparatus according to any one of [A01] to [A08], in which the wavelength conversion layer in each of the light emitting devices includes light scattering particles.
[A10] The display apparatus according to any one of [A01] to [A09], in which the wavelength selection layer in each of the light emitting devices includes light scattering particles.
[A11] The display apparatus according to any one of [A01] to [A10], in which the wavelength conversion layer in each of the light emitting devices further increases a light-scattering particle layer.
[A12] The display device according to [A11], in which the total thickness of the thickness of the light-scattering particle layer and the thickness of the color conversion layers is equal between the light emitting devices.
[A13] The display apparatus according to any one of [A01] to [A12], in which an on-chip micro-lens is provided on a light emitting side of the wavelength selection layer in each of the light emitting devices.
[A14] The display apparatus according to any one of [A01] to [A13], in which the light generating unit in each of the light emitting devices is coupled to drive circuitry provided on a base.
[A15] The display apparatus according to any one of [A01] to [A14], in which a transparent material member is provided between the light generating unit and the wavelength conversion layer in each of the light emitting devices.
[A16] The display apparatus according to any one of [A01] to [A14], in which a transparent material member is provided between the wavelength conversion layer and the wavelength selection layer in each of the light emitting devices.
[A17] The display apparatus according to [A15] or [A16], in which a space (gap) is provided more adjacent to the light generating unit than the transparent material member is.
[A18] The display apparatus according to [A17], in which a space (gap) is provided between the wavelength conversion layer and the wavelength selection layer.
[A19] The display apparatus according to [A17], in which a space (gap) is provided between the light generating unit and the wavelength conversion layer.
[A20] The display apparatus according to [A15], in which the first wavelength conversion layer, the second wavelength conversion layer, and the third wavelength conversion layer are formed on the transparent material member.
[A21] The display apparatus according to any one of [A01] to [A20], in which the light generating unit in each of the light emitting devices is a light emitting diode.
[A22] The display apparatus according to any one of [A01] to [A20], in which the light generating unit in each of the light emitting devices is an organic electroluminescent device.
[A23] The display apparatus according to any one of [A01] to [A22], in which a light shutter means is provided between the wavelength conversion layer and the wavelength selection layer in each of the light emitting devices.
[A24] The display apparatus according to [A23], in which the light shutter means is a liquid crystal display of a transmission type.
[A25] The light emitting device according to any one of [A01] to [A24], in which the light emitting devices are separated from each other by a sidewall (partition wall).
[A26] The display apparatus according to [A25], in which the wavelength conversion layer is surrounded by the sidewall (partition wall) in each of the light emitting devices.
[A27] The display apparatus according to [A25], in which the light generating unit and the wavelength conversion layer are surrounded by the sidewall (partition wall) in each of the light emitting devices.
[A28] The display apparatus according to any one of [A25] to [A27], in which a light reflection layer is formed on an inner surface of the sidewall.
[A29] The display apparatus according to any one of [A01] to [A28], in which the total thickness of the thickness of the wavelength conversion layer and the thickness of the wavelength selection layer is equal between the light emitting devices.
[A30] The display apparatus according to any one of [A01] to [A29], in which an optical crosstalk suppression unit is provided in a region between the light emitting devices.
[A31] The display apparatus according to any one of [A01] to [A30], in which the color conversion layer includes a particulate color conversion material embedded in a filler.
[B01] <<Light Emitting Device>>

A light emitting device including:

a light generating unit that generates light having a wavelength λ₀; and

a wavelength conversion layer that includes a color conversion layer including a particulate color conversion material, the particulate color conversion material converting the color of the light having the wavelength λ₀ emitted from the light generating unit, in which

the color conversion layer has a thickness determined on a basis of the wavelength λ″ (where λ″>λ₀ holds) of light emitted from the wavelength conversion layer.
[B02] The light emitting device according to [B01], in which the particulate color conversion material includes quantum dots.
[B03] The light emitting device according to [B01] or [B02], further including a wavelength selection layer that the light emitted from the wavelength conversion layer enters.
[C01] <<Light Emitting Member>>

A light emitting member including

a first light emitting portion, a second light emitting portion, and a third light emitting portion, in which

the first light emitting portion includes a first wavelength conversion layer including a first color conversion layer, the first color conversion layer having a thickness T₁ and including a particulate color conversion material, the particulate color conversion material converting a color of light having a wavelength λ₀ emitted from a light generating unit,

the second light emitting portion includes a second wavelength conversion layer including a second color conversion layer, the second color conversion layer having a thickness T₂ and including a particulate color conversion material, the particulate color conversion material converting a color of light having a wavelength λ₀ emitted from a light generating unit,

the third light emitting portion includes a third wavelength conversion layer including a third color conversion layer, the third color conversion layer having a thickness T₃ and including a particulate color conversion material, the particulate color conversion material converting a color of light having a wavelength λ₀ emitted from a light generating unit,

T₁<T₂≤T₃ is satisfied, and

the peak wavelength of a light spectrum of light emitted from the first wavelength conversion layer is different from the peak wavelength of a light spectrum of light emitted from the second wavelength conversion layer and the peak wavelength of a light spectrum of light emitted from the third wavelength conversion layer.
[C02] The light emitting member according to [C01], in which the particulate color conversion material in each of the light emitting portions includes a first quantum dot that converts light having a wavelength λ₀ into light having a wavelength λ₂″ (where λ₂″>λ₀ holds) and a second quantum dot that converts light having a wavelength λ₀ into light having a wavelength λ₃″ (where λ₃″>λ₂″>λ₀ holds).
[C03] The light emitting member according to [C02], in which the second quantum dot further converts light having a wavelength μ₂″ into light having a wavelength λ₃″.

[C04] The light emitting member according to [C02] or [C03], satisfying T₁<T₂=T₃.
[C05] The light emitting member according to [C02] or [C03], satisfying T₁<T₂<T₃.
[C06] The light emitting member according to any one of [C01] to [C05], in which

the wavelength conversion layer in each of the light emitting portions further includes a spacer layer, and

the total thickness of the thickness of the spacer layer and the thickness of the color conversion layer is equal between the light emitting portions.

[C07] The light emitting member according to [C06], in which the spacer layer is positioned on a light incident side of the color conversion layer.

[C08] The light emitting member according to [C06], in which the spacer layer is positioned on a light emitting side of the color conversion layer.

[C09] The light emitting member according to any one of [C01] to [C08], in which the wavelength conversion layer in each of the light emitting portions includes light scattering particles.

[C10] The light emitting member according to any one of [C01] to [C09], in which the wavelength conversion layer in each of the light emitting portions further includes a light-scattering particle layer.

[C11] The light emitting member according to [C10], in which the total thickness of the thickness of the light-scattering particle layer and the thickness of the color conversion layers is equal between the light emitting portions.

[C12] The light emitting member according to any one of [C01] to [C11], in which a wavelength selection layer is provided more adjacent to a light emitting side than the wavelength conversion layer is in each of the light emitting portions.

[C13] The light emitting member according to [C12], in which the wavelength selection layer in each of the light emitting portions includes light scattering particles.

[C14] The light emitting member according to [C12] or [C13], in which a transparent material member is provided between the wavelength conversion layer and the wavelength selection layer in each of the light emitting portions.

[C15] The light emitting member according to [C14], in which a space (gap) is provided more adjacent to the light generating unit than the transparent material member is.

[C16] The light emitting member according to any one of [C01] to [C13], in which the wavelength conversion layer is provided on the transparent material member in each of the light emitting portions.

[C17] The light emitting member according to any one of [C01] to [C16], in which a light shutter means is provided between the wavelength conversion layer and the wavelength selection layer in each of the light emitting portions.

[C18] The light emitting member according to [C17], in which the light shutter means is a liquid crystal display of a transmission type.

[C19] The light-emitting portion according to any one of [C01] to [C18], in which the light emitting portions are separated from each other by a sidewall (partition wall).

[C20] The light emitting member according to [C19], in which the wavelength conversion layer is surrounded by the sidewall (partition wall) in each of the light emitting portions.

[C21] The light emitting member according to [C19] or [C20], in which a light reflection layer is formed on an inner surface of the sidewall.

[C22] The light emitting member according to any one of [C01] to [C21], in which the total thickness of the thickness of the wavelength conversion layer and the thickness of the wavelength selection layer is equal between the light emitting portions.

[C23] The light emitting member according to any one of [C01] to [C22], in which an optical crosstalk suppressing unit is provided in a region between the light emitting portions.

[C24] The light emitting member according to any one of [C01] to [C23], in which the color conversion layer includes a particulate color conversion material embedded in a filler.

### REFERENCE SIGNS LIST

10 . . . first light emitting device, 11, 11′ . . . first light generating unit (light generating unit), 12 . . . first wavelength conversion layer (wavelength conversion layer), 13 . . . first color conversion layer (color conversion layer), 14 . . . first wavelength selection layer (wavelength selection layer), 20 . . . second light emitting device, 21, 21′ . . . second light generating unit (light generating unit), 22 . . . second wavelength conversion layer (wavelength conversion layer), 23 . . . second color conversion layer (color conversion layer), 24 . . . second wavelength selection layer (wavelength selection layer), 30 . . . third light emitting device, 31, 31′ . . . third light generating unit (light generating unit), 32 . . . third wavelength conversion layer (wavelength conversion layer), 33 . . . third color conversion layer (color conversion layer), 34 . . . third wavelength selection layer (wavelength selection layer), 40 . . . filler (matrix), 51 . . . first compound semiconductor layer, 52 . . . second compound semiconductor layer, 53 . . . active layer (light emitting layer), 54 . . . insulating layer, 55 . . . first electrode, 56 . . . second electrode, 57 . . . light reflection film, 58 . . . cutout, 60 . . . sidewall (partition wall), 61 . . . light reflection layer, 70 . . . spacer layer, 70′ . . . spacer forming layer, 70″ . . . template, 71 . . . light-scattering particle layer, 72 . . . on-chip micro-lens, 72′ . . . planarizing layer, 73, 74 . . . transparent material member, 73A . . . first surface of the transparent material member, 73B . . . second surface of transparent material member, 73′, 74′ . . . adhesive layer, 75 . . . space (gap), 80 . . . support base, 81 . . . ultraviolet curable resin material, 90 . . . base, 91, 92 . . . bump, 93, 94 . . . coupling portion, 95 . . . light shutter means, 96 . . . insulating film

1. A display apparatus comprising
a plurality of light emitting device units each including a first light emitting device, a second light emitting device, and a third light emitting device, wherein
the first light emitting device includes
a first light generating unit that generates light having a wavelength λ₀,
a first wavelength conversion layer that includes a first color conversion layer having a thickness T₁ and including a particulate color conversion material, the particulate color conversion material converting a color of the light having the wavelength λ₀ emitted from the first light generating unit, and
a first wavelength selection layer that the light emitted from the first wavelength conversion layer enters and that emits light having a wavelength λ₁′,
the second light emitting device includes
a second light generating unit that generates light having a wavelength λ₀,
a second wavelength conversion layer that includes a second color conversion layer having a thickness T₂ and including a particulate color conversion material, the particulate color conversion material converting a color of the light having the wavelength λ₀ emitted from the second light generating unit, and
a second wavelength selection layer that the light emitted from the second wavelength conversion layer enters and that emits light having a wavelength λ₂′,
the third light emitting device includes
a third light generating unit that generates light having a wavelength λ₀,
a third color conversion layer that includes a third color conversion layer having a thickness T₃ and including a particulate color conversion material, the particulate color conversion material converting a color of the light having the wavelength λ₀ emitted from the third light generating unit, and
a third wavelength selection layer that the light emitted from the third wavelength conversion layer enters and that emits light having a wavelength λ₃′ (where λ1′<λ2′<λ3′ holds), and
T₁<T₂≤T₃ is satisfied.

2. The display apparatus according to claim 1, wherein the particulate color conversion material in each of the light emitting devices includes a first quantum dot that converts light having a wavelength λ₀ into light having a wavelength λ₂″ (where λ₂″>λ₀ holds) and a second quantum dot that converts light having a wavelength λ₀ into light having a wavelength λ₃″ (where λ₃″>λ₂″>λ₀ holds).

3. The display apparatus according to claim 2, satisfying T₁<T₂=T₃.

4. The display apparatus according to claim 2, satisfying T₁<T₂<T₃.

5. The display apparatus according to claim 1, wherein the wavelength conversion layer in each of the light emitting devices further includes a spacer layer, and
a total thickness of a thickness of the spacer layer and a thickness of the color conversion layer is equal between the light emitting devices.

6. The display apparatus according to claim 1, wherein the wavelength conversion layer in each of the light emitting devices includes light scattering particles.

7. The display apparatus according to claim 1, wherein the wavelength selection layer in each of the light emitting devices includes light scattering particles.

8. The display device according to claim 1, wherein the wavelength conversion layer in each of the light emitting devices further includes a light-scattering particle layer.

9. The display device according to claim 1, wherein an on-chip micro-lens is provided on a light emitting side of the wavelength selection layer in each of the light emitting devices.

10. The display apparatus according to claim 1, wherein the light generating unit in each of the light emitting devices is coupled to drive circuitry provided on a base.

11. The display apparatus according to claim 1, wherein a transparent material member is provided between the light generating unit and the wavelength conversion layer in each of the light emitting devices.

12. The display apparatus according to claim 1, wherein a transparent material member is provided between the wavelength conversion layer and the wavelength selection layer in each of the light emitting devices.

13. The display apparatus according to claim 1, wherein the light generating unit in each of the light emitting devices comprises a light emitting diode.

14. The display apparatus according to claim 1, wherein the light generating unit in each of the light emitting devices comprises an organic electroluminescent device.

15. The display apparatus according to claim 1, wherein a light shutter means is provided between the wavelength conversion layer and the wavelength selection layer in each of the light emitting devices.

16. A light emitting device comprising:
a light generating unit that generates light having a wavelength λ₀; and
a wavelength conversion layer that includes a color conversion layer including a particulate color conversion material, the particulate color conversion material converting a color of the light having the wavelength emitted from the light generating unit, wherein
the color conversion layer has a thickness determined on a basis of the wavelength λ″ (where λ″>λ₀ holds) of light emitted from the wavelength conversion layer.

17. The light emitting device according to claim 16, wherein the particulate color conversion material includes quantum dots.

18. The light emitting device according to claim 16, further comprising a wavelength selection layer that the light emitted from the wavelength conversion layer enters.

19. A light emitting member comprising
a first light emitting portion, a second light emitting portion, and a third light emitting portion, wherein
the first light emitting portion includes a first wavelength conversion layer including a first color conversion layer, the first color conversion layer having a thickness T₁ and including a particulate color conversion material, the particulate color conversion material converting a color of light having a wavelength λ₀ emitted from a light generating unit,
the second light emitting portion includes a second wavelength conversion layer including a second color conversion layer, the second color conversion layer having a thickness T₂ and including a particulate color conversion material, the particulate color conversion material converting a color of light having a wavelength λ₀ emitted from a light generating unit,
the third light emitting portion includes a third wavelength conversion layer including a third color conversion layer, the third color conversion layer having a thickness T₃ and including a particulate color conversion material, the particulate color conversion material converting a color of light having a wavelength λ₀ emitted from a light generating unit,
T₁<T₂≤T₃ is satisfied, and
a peak wavelength of a light spectrum of light emitted from the first wavelength conversion layer is different from a peak wavelength of a light spectrum of light emitted from the second wavelength conversion layer and a peak wavelength of a light spectrum of light emitted from the third wavelength conversion layer.
